(19) United States
(12) Patent Application Publication
(10) Pub. No.: US 2014/0201110 A1
(43) Pub. Date: Jul. 17, 2014

(54) SERVER DEVICE, ELECTRONIC APPARATUS, COMMUNICATION SYSTEM, AND INFORMATION PROCESSING METHOD

(71) Applicant: SHARP KABUSHIKI KAISHA, Osaka (JP)

(72) Inventor: Hiroki SATO, Osaka (JP)

(73) Assignee: SHARP KABUSHIKI KAISHA, Osaka (JP)

(21) Appl. No.: 14/157,103

(22) Filed: Jan. 16, 2014

(30) Foreign Application Priority Data
Jan. 17, 2013 (JP) 2013-006312

(51) Int. Cl. G01R 21/133; G06Q 30/02; G06Q 50/06

(52) U.S. Cl. CPC G01R 21/133; G06Q 50/06; G06Q 30/0283
USPC 705/412; 702/60

(57) ABSTRACT

A terminal device that is an electronic apparatus communicates with a server device that communicates with a communication device located at one premises. The terminal device receives, based on obtaining the electricity usage quantity by the one premises from a wireless router, information representing the total quantity of electricity usage quantity and the total figure of the electricity rate by the one premises, and the total quantity of electricity usage quantity and the total figure of the electricity rate by another premises over a predetermined term. The terminal device provides a display based on the received total quantity of electricity usage quantity and the total figure of the electricity rate. Accordingly, the user can readily determine whether electricity is used economically as compared to another premises.

This nonprovisional application is based on Japanese Patent Application No. 2013-006312 filed on Jan. 17, 2013 with the Japan Patent Office, the entire contents of which are hereby incorporated by reference.

### BACKGROUND OF THE INVENTION

1. Field of the Invention

The present invention relates to a server device, an electronic apparatus communicating with the server device, a communication system including the server device and the electronic apparatus, and an information processing method of the server device or electronic apparatus.

2. Description of the Background Art

There is conventionally known a device that notifies an expenditure plan of a lower electricity rate than the expenditure plan currently under contract based on the usage status of each device that uses electric power.

Japanese Patent Laying-Open No. 2011-258020 (PTD 1) discloses a server device corresponding to the aforementioned device, receiving and storing the usage time zone and usage quantity of electricity of each of a plurality of devices sent from a transmission device located at each household of a contractor. The server device selects an apparatus from a plurality of apparatuses in the order of a higher usage of electricity. The server device calculates, every time the electricity usage time zone of the selected apparatus is shifted for a predetermined time, an electricity rate according to another price contract differing from the price contract currently entered by the contractor, and determines whether the expenditure may become lower than the price contract currently entered. When a determination is made that the expenditure will become lower, the server device determines the shifted electricity usage time zone as the recommended time zone for the selected device to use electricity, and notifies the contractor about the time zone together with another price contract.

Further, Japanese Patent Laying-Open No. 2001-352676 (PTD 2) discloses an energy conservation system presenting a condition in reducing the electricity rate of a user. PTD 2 discloses an energy conservation proposal system particularly directed to reliably estimating the curtailed figure of the electricity rate for the user.

Further, “Denryoku Mieruka Shisutemu” (Electricity Looking System), [on line][Jan. 10, 2013 search], Internet <URL:http://www.sharp.co.jp/sunvista/product/mieruka/>” (Non-Patent Document 1) discloses a system of giving a comprehensive look at the electricity usage quantity and the like. Specifically, Non-Patent Document 1 discloses a configuration of displaying the electricity consumption over one month for each apparatus, a configuration of displaying a graph showing the change in the electricity consumption on an hourly basis.

### SUMMARY OF THE INVENTION

However, the conventional system configuration does not allow whether electricity is used more economically than others by just comparing the electricity rate with the electricity rate of another residence, since the amount of electricity usage differs between each of the residences.

In view of the foregoing, an object of the present invention is to provide a server device, an electronic apparatus, a communication system, and an information processing method to allow the electricity user including an electricity contractor to readily determine whether electricity is used economically as compared to other residences.

According to an aspect of the present invention, a server device communicates with a first communication device located at a first residence, a second communication device located at a second residence, and an electronic apparatus used by a user of the first communication device. The server device includes a reception unit receiving an electricity usage quantity by the first residence from the first communication device and an electricity usage quantity by the second residence from the second communication device; a storage unit storing each electricity usage quantity in correspondence with a time and date when the electricity is used, and rate information representing the electricity rate on a time zone basis; a total quantity calculation unit calculating the total quantity of electricity usage quantity by the first residence and the total quantity of electricity usage quantity by the second residence over a predetermined first term based on each electricity usage quantity; a total figure calculation unit calculating the total figure of the electricity rate by the first residence and the total figure of the electricity rate by the second residence over the first term based on each electricity usage quantity stored in correspondence with the time and date, and the rate information; and a transmission unit transmitting to the electronic apparatus the total quantity of electricity usage quantity and the total figure of the electricity rate by the first residence in association, and the total quantity of electricity usage quantity and the total figure of the electricity rate by the second residence in association.

Preferably, the total quantity calculation unit further calculates the total quantity of electricity usage quantity by the first residence over a second term previous to and identical in length with the first term. The total figure calculation unit further calculates the total figure of electricity rate at the first residence over the second term. The transmission unit also transmits to the electronic apparatus the total quantity of electricity usage quantity and the total figure of the electricity rate in association by the first residence over the second term.

Preferably, the server device further includes a unit price calculation unit calculating the unit price per unit electricity for each of the first and second residences over the first term. The transmission unit also transmits to the electronic apparatus first unit price information representing the unit price for the first residence and second unit price information representing the unit price for the second residence.

Preferably, the server device further communicates with a plurality of third communication devices differing from the first communication device and second communication device. Each of the third communication devices is located at a residence differing from and excluding the first residence and second residence. The unit price calculation unit calculates the unit price of electricity rate per unit electricity at each residence where a third communication device is located. The transmission unit transmits to the electronic apparatus ranking information representing the ranking of unit price of the first residence among the unit price of the first residence, the unit price of the second residence, and the unit price of each residence where a third communication device is located.

Preferably, the reception unit further receives the electricity usage quantity by each of a plurality of household appliances located at the first residence. The first term is one month of the present month. The total quantity calculation unit also calculates an estimation value of the total quantity of electricity usage quantity by the first residence when the first term has elapsed from the total quantity of electricity usage quantity by the first residence at the current point in time. The server device further includes a ratio calculation unit calculating the ratio of the electricity usage quantity by each household appliance to the estimation value, and the ratio of the electricity usage by each household appliance to the electricity usage quantity by the first residence over the second term. The transmission unit also transmits to the electronic apparatus the ratio information representing each calculated ratio.

Preferably, the total figure calculation unit further calculates an estimation value of the total figure of the electricity rate by the first residence when the first term has elapsed in a case where at least one of the plurality of household appliances is replaced by purchase with a preliminarily household appliance of a manufacturer identical to or different from the manufacturer of the household appliance. The transmission unit transmits to the electronic apparatus the total figure of the electricity rate when the household appliance is replaced by purchase.

Preferably, the storage unit further stores a first threshold value related to a unit price. The server device further includes a determination unit determining whether the unit price of the first residence and the unit price of the second residence is greater than or equal to the first threshold value. The transmission unit transmits to the electronic apparatus a message prompting saving-on money when the unit price of the first residence is greater than or equal to the first threshold value.

Preferably, the storage unit further stores a second threshold value related to an electricity usage quantity. The determination unit further determines whether the electricity usage quantity by the first residence and by the second residence is greater than or equal to the second threshold value. The transmission unit transmits a message prompting saving-on electricity to the electronic apparatus when the electricity usage quantity by the first residence is greater than or equal to the second threshold value.

Preferably, the server device obtains external environmental information including at least one of the weather and temperature on a time zone basis from an external device. The storage unit stores each obtained electricity usage quantity in association with the obtained external environmental information. The transmission unit further transmits to the electronic apparatus the first unit price information and the second unit price information over the first term, and the external environmental information over the first term.

Preferably, the storage unit stores, as rate information, the rate information according to each of a plurality of contracts related to the electricity rate, and a contract applied to each of the first residence and the second residence from the plurality of contracts. The transmission unit transmits to the electronic apparatus information to identify the contract applied to the first residence in association with the total quantity of electricity usage quantity and the total figure of the electricity rate at the first residence, and information to identify the contract applied to the second residence in association with the total quantity of electricity usage quantity and the total figure of the electricity rate at the second residence.

Preferably, the storage unit stores, as rate information, the rate information according to each of a plurality of contracts related to the electricity rate, and the contract applied to the first residence among the plurality of contracts. The server device further includes a provisional rate calculation unit calculating the total figure of electricity rate of a specified term at the first residence assuming that a contract from the plurality of contracts, differing from the contract applied to the first residence, is entered. The transmission unit transmits to the electronic apparatus the total figure of the electricity rate assuming that the different contract has been entered.

According to another aspect of the present invention, a server device communicates with a first communication device located at a first residence, a second communication device located at a second residence, and an electronic apparatus used by a user of the first communication device. The server device includes a reception unit receiving an electricity usage quantity by the first residence from the first communication device and an electricity usage quantity by the second residence from the second communication device, a storage unit storing each electricity usage quantity in correspondence with a time and date when electricity is used, and rate information representing an electricity rate on a time zone basis; a unit price calculation unit calculating a unit price of the electricity rate per unit electricity at each of the first residence and second residence over a predetermined first term based on each electricity usage quantity and rate information, and a transmission unit transmitting to the electronic apparatus first unit price representing the unit price of the first residence and second unit price representing the unit price of the second residence.

According to a further aspect of the present invention, the server device communicates with a first communication device located at a first residence, a second communication device located at a second residence, and an electronic apparatus used by a user of the first communication device. The server device includes a reception unit receiving an electricity usage quantity by the first residence from the first communication device and an electricity usage quantity by the second residence from the second communication device; a storage unit storing each electricity usage quantity in correspondence with the time and date when the electricity is used, and rate information representing the electricity rate on a time zone basis; a total quantity calculation unit calculating the total quantity of electricity usage quantity by the first residence and the total quantity of electricity usage quantity by the second residence over a predetermined first term based on each electricity usage quantity; a total figure calculation unit calculating the total figure of the electricity rate by the first residence and the total figure of the electricity rate by the second residence over the first term based on each electricity usage quantity stored in correspondence with a time and date, and the rate information; a generation unit generating image data having the total quantity of electricity usage quantity by the first residence associated with the total figure of the electricity rate by the first residence and the total quantity of electricity usage quantity by the second residence associated with the total figure of the electricity rate by the second residence; and a transmission unit transmitting the generated image data to the electronic apparatus.

According to still another aspect of the present invention, an electronic apparatus communicates with a server device communicating with a communication device located at one residence. The electronic apparatus includes a reception unit receiving from the server device information representing the total quantity of electricity usage quantity and the total figure of the electricity rate at the one residence over a predetermined term, and the total quantity of electricity usage quantity and the total figure of the electricity rate at a residence differing from the one residence over a predetermined term, based on the server device obtaining the electricity usage quantity by the one residence from the communication device; and an output unit providing an output based on the received total quantity of electricity usage quantity and the total figure of the electricity rate.

Preferably, the output unit provides a display representing the unit price per unit electricity for each of the one residence and another residence.

Preferably, the output unit displays the total quantity of electricity usage quantity and the total figure of the electricity rate at the one residence, and at the other residence in a two-dimensional graph. One of the vertical axis and horizontal axis of the graph represents the total quantity of electricity usage quantity and the other represents the total figure of the electricity rate.

According to still another aspect of the present invention, a communication system includes a first communication device located at a first residence, a second communication device located at the second residence, an electronic apparatus used by a user of the first communication device, and a server device. The server device includes a reception unit receiving an electricity usage quantity by the first residence from the first communication device and the electricity usage quantity by the second residence from the second communication device; a storage unit storing each electricity usage quantity in correspondence with a time and date when electricity is used, and rate information representing an electricity rate on a time zone basis; a total quantity calculation unit calculating the total quantity of electricity usage quantity by the first residence and the total quantity of electricity usage quantity by the second residence over a predetermined term based on each electricity usage quantity; a total figure calculation unit calculating the total figure of the electricity rate by the first residence and the total figure of the electricity rate by the second residence over the predetermined term based on each electricity usage quantity stored in correspondence with the time and date, and the rate information; and a transmission unit transmitting to the electronic apparatus the total quantity of electricity usage quantity and the total figure of the electricity rate by the first residence in association, and the total quantity of electricity usage quantity and the total figure of the electricity rate by the second residence in association. The electronic apparatus includes a reception unit receiving information representing the total quantity of electricity usage quantity and the total figure of the electricity rate at the first residence over the predetermined time and the total quantity of electricity usage quantity and the total figure of the electricity rate at the second residence over a predetermined term from the server device; and an output unit providing an output based on the received total quantity of electricity usage quantity and the total figure of the electricity rate.

According to still another aspect of the present invention, an information processing method is executed at a server device communicating with a first communication device located at a first residence, a second communication device located at a second residence, and an electronic apparatus used by a user of the first communication device. The information processing method includes: receiving, by the server device, an electricity usage quantity by a first residence from the first communication device and receiving an electricity usage quantity by a second residence from the second communication device; storing, by the server device, each electricity usage quantity in correspondence with a time and date when electricity is used, and rate information representing an electricity rate on a time zone basis; calculating, by the server device, a total quantity of electricity usage quantity by the first residence and a total quantity of electricity usage quantity by the second residence over a predetermined first term based on each electricity usage quantity; calculating, by the server device, a total figure of the electricity rate at the first residence and a total figure of the electricity rate at the second residence over the first term based on each electricity usage quantity stored in correspondence with the time and date, and the rate information; and transmitting, by the server device, to the electronic apparatus the total quantity of electricity usage quantity and the total figure of the electricity rate at the first residence in association, and the total quantity of electricity usage quantity and the total figure of the electricity rate at the second residence in association.

According to still another aspect of the present invention, an information processing method is executed at an electronic apparatus communicating with a server device communicating with a communication device located at a residence. The information processing method includes: based on obtaining the electricity usage quantity by one residence from the communication device by the server device, receiving, by the electronic apparatus, information representing the total quantity of electricity usage quantity and the total figure of the electricity rate at the one residence and information representing the total quantity of electricity usage quantity and the total figure of the electricity rate at another residence differing from the one residence over a predetermined term; and providing, by the electronic apparatus, an output based on the received total quantity of electricity usage quantity and total figure of the electricity rate.

According to the present invention, a determination can be readily made as to whether an electricity user including an electricity contractor is using electricity economically as compared to another residence.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 schematically represents a system configuration of a communication system 11.

FIG. 2 represents an example of an image displayed on a monitor of a terminal device 101.

FIG. 3 represents a hardware configuration of a server device 201.

FIG. 4 represents a hardware configuration of terminal device 101.

FIG. 5 is a diagram to describe a functional configuration of server device 201 and terminal device 101.

FIG. 6 is a sequence diagram to describe a process performed at communication system 11.

FIG. 7 is a schematic diagram of a system configuration of a communication system 12.

FIG. 8 is a schematic diagram of a system configuration of a communication system 13.

FIG. 9 is a diagram to describe an image displayed at terminal device 101.

FIG. 10 is a diagram to describe a functional configuration of a server device 201A.

FIG. 11 is a diagram to describe a screen display based on ratio information at terminal device 101.

FIG. 12 is a diagram to describe a data table 71 stored in a storage unit 211 of server device 202.

FIG. 13 represents an image subsequent to transition when a predetermined instruction is applied to terminal device 101 at the state of FIG. 11 (B).

FIG. 14 is a diagram to describe a functional configuration of server device 202.

FIG. 15 is a visual representation of the total quantity of electricity usage quantity for the present month, the total figure of the electricity rate for the present month, and the unit price for the present month at each premises, in the form of a graph, stored by server device 202A.

FIG. 16 represents a data table 72 showing the tendency and advice.

FIG. 17 represents an image displayed at terminal device 101 when a plot for premises 901 is positioned at a region Q.

FIG. 18 is a diagram to describe a functional configuration of server device 202A.

FIG. 19 represents a display screen by terminal device 101.

FIG. 20 represents another display screen by terminal device 101.

FIG. 21 is a diagram to describe a functional configuration of a server device 202B.

FIG. 22 is a diagram representing a display screen by terminal device 101.

FIG. 23 represents another display screen by terminal device 101.

FIG. 24 represents a display screen when another contract plan is selected.

FIG. 25 represents a transition image when (1) YES in FIG. 24 is to be selected.

FIG. 26 is a diagram to describe a functional configuration of a server device 202C.

### DESCRIPTION OF THE PREFERRED EMBODIMENTS

A communication system according to each embodiment of the present invention will be described hereinafter with reference to the drawings. In the following description, the same elements have the same reference characters allotted, and their designation and function are also identical. Therefore, detailed description thereof will not be repeated.

### First Embodiment

### A. System Configuration

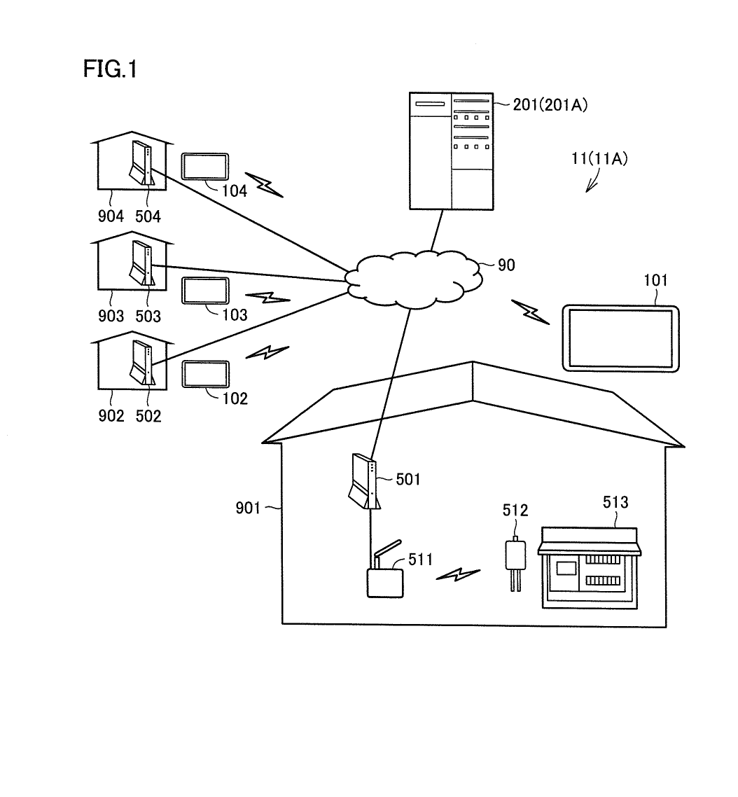

FIG. 1 is a schematic diagram of a system configuration of a communication system 11 according to the first embodiment. Referring to FIG. 1, communication system 11 includes terminal devices 101-104, a server device 201, wireless routers 501-504 that are access points, a relay 511, a current transformer (CT) sensor 512, and a distribution board 513. Terminal devices 101-104, server device 201, and wireless routers 501-504 are connected on a network 90 such as the Internet, all configured to allow communication therebetween.

Terminal device 101 is used by the user of wireless router 501. Terminal devices 102, 103 and 104 are used by the user of wireless router 502, wireless router 503, and wireless router 504, respectively. Terminal devices 101-104 are tablet terminals in the present embodiment. However, terminal devices 101-104 are not limited to tablet terminals, and any electronic apparatus having a communication capability and display capability may be employed.

Wireless router 501, relay 511, CT sensor 512, and distribution board 513 are installed on premises 901. Wireless routers 502, 503 and 504 are installed on premises 902, 903, and 904, respectively. Although not shown, a relay, a CT sensor, and a distribution board are also installed at premises 902-904, likewise with premises 901.

Distribution board 513 distributes the electricity transmitted to premises 901 through the power line of an electric power company. Distribution board 513 includes, from the upstream side, an ampere breaker (service breaker), an earth leakage breaker, and a wiring breaker (safety breaker). The ampere breaker automatically cuts off the electric power when electric power exceeding a predetermined amount (for example, the contracted current) flows. The wiring breaker is attached to each branch circuit delivering electric power from distribution board 513 to each room on premises 901. When shorting occurs due to failure of electronic equipment or cord at a room or when excessive current flows due to the over usage of an electric apparatus, electric power is automatically cut.

CT sensor 512 serves to measure AC current. Specifically, CT sensor 512 is arranged at an upstream side of the earth leakage breaker to measure current used at premises 901. CT sensor 512 calculates the electricity usage quantity at premises 901 from the current value obtained by measurement. CT sensor 512 transmits the calculated electricity usage quantity to relay 511.

Relay 511 relays the electricity usage quantity sent from CT sensor 512 to wireless router 501. Wireless router 501 transmits the electricity usage quantity received from CT sensor 512 via relay 511 to server device 201.

Although the above description is based on each device located on premises 901, a similar operation is also carried out for the devices on premises 902-904. Wireless routers 502-504 send the electricity usage quantity by each of premises 902-904 to server device 201. Accordingly, server device 201 can obtain the electricity usage quantity by each of premises 901-904. The process executed at server device 201 and at terminal devices 101-104 will be described afterwards.

For the sake of convenience, it is assumed that the user of terminal device 101 is the contractor of electricity on premises 901. Similarly, it is assumed that the user of terminal device 102, the user of terminal device 103, and the user of terminal device 104 are the electricity contractors on premises 902, premises 903 and premises 904, respectively.

At server device 201, wireless router 501 and terminal device 101 are associated by, for example, a device ID, a user ID of each device or the like. Similarly, wireless routers 502, 503 and 504 are set in a one-to-one correspondence with terminal devices 102, 103, and 104, respectively, at server device 201.

For the sake of convenience, FIG. 1 shows the state where four wireless routers 501-504 and four terminal devices 101-104 are connected in a manner allowing communication with server device 201. However, it is assumed that more wireless routers and terminal devices are connected to server device 201 in communication system 11.

### B. Process Overview

b1. Process Overview of Server Device 201

For the sake of convenience, description will be provided focusing on data to be transmitted to terminal device 101, among terminal devices 101-104.

Server device 201 transmits to terminal device 101 information about the total quantity of electricity usage quantity by each of premises 901, 902, 903, 904 . . . , information about the total figure of the electricity rate at each of premises 901, 902, 903, 904 . . . , and information about the unit price of the electricity rate at each of premises 901, 902, 903, 904 . . . .

Specifically, server device 201 responds to a request from terminal device 101 according to an aspect to transmit to terminal device 101 information about the total quantity of electricity usage quantity, the total figure of the electricity rate, and the unit price for each premises in the present month (precisely, from the first day of the month when the request was accepted to the day of accepting the request). Further, server device 201 transmits to terminal device 101 information about the total quantity of electricity usage quantity, the total figure of the electricity rate, and the unit price by premises 901 for the previous month.

Further, server device 201 transmits to terminal device 101 information representing the average value of the unit price, and information representing two unit prices (two threshold values) serving as a reference. Server device 201 also transmits to terminal device 101 an estimation value of the total quantity of electricity usage quantity, and the estimation value of the total figure of the electricity rate on premises 901 for the present month. Server device 201 also transmits to terminal device 101 a comment based on the unit price on the electricity usage quantity at premises 901.

More specifically, server device 201 transmits to terminal device 101 the aforementioned various types of information for other premises 902, 903, 904, . . . at a predetermined district identical to premises 901 (for example, within the same electric company service area, the same prefecture, the same city, or the same town). Terminal device 101 is preferably configured to allow specifying the aforementioned district.

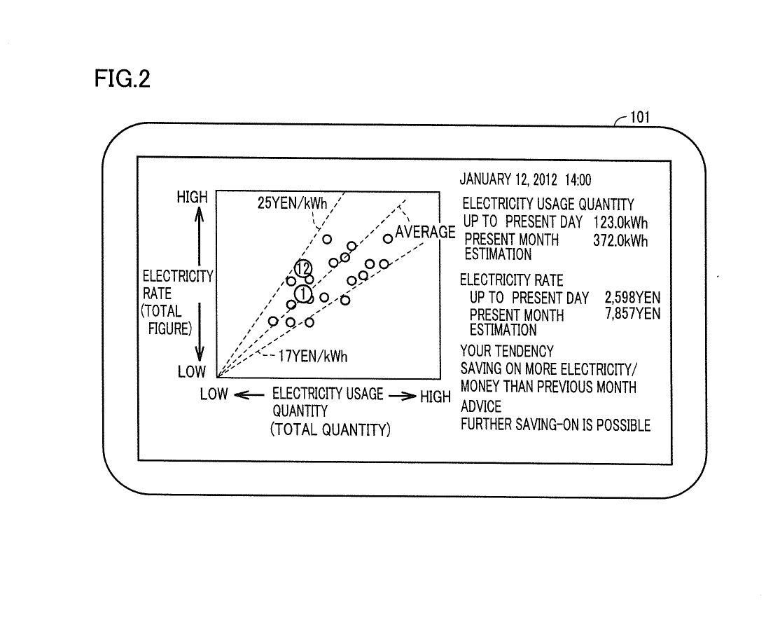

Although the above description has been provided based on an exemplified configuration in which server device 201 transmits information about the unit price to terminal device 101, the configuration is not limited thereto. Terminal device 101 may be configured to calculate the unit price based on the information about the total quantity of electricity usage quantity and the total figure of the electricity rate. Both server device 201 and terminal device 101 do not have to carry out the calculation of the unit price in order to display the image of FIG. 2 that will be described afterwards.

b2. Process Overview of Terminal Device 101

Terminal device 101 receives the aforementioned various data from server device 201 to display an image based on the received data. An image displayed on the monitor (touch screen) of terminal device 101 will be described hereinafter. An application program to generate and display the image is prestored in terminal device 101.

FIG. 2 represents an example of an image displayed on the monitor of terminal device 101. Referring to FIG. 2, a graph with the total quantity (kWh) of electricity usage quantity plotted along the horizontal axis and the total figure (Japanese yen) of the electricity rate plotted along the vertical axis is shown on the monitor of terminal device 101. In this graph, the circle with number “12” represents the data of December (previous month) on premises 901, whereas the circle with number “1” represents the data of January (present month) on premises 901. The other circles (open circle) represent the data of January (present month) on any premises other than premises 901, i.e. premises 902, 903, 904 . . . . As used herein, the inclination of the line connecting each circle and the origin (zero for both the electricity usage quantity and electricity rate) represents the unit price.

The graph includes lines representing the average of the unit price (the middle broken line), the first threshold value (25 yen/kWh) of the unit price (the upper side broken line), and the second threshold value (17 yen/kWh) of the unit price (the lower side broken line).

The monitor of terminal device 101 provides the display of the total quantity of electricity usage quantity to the present date, and the estimation value of the total quantity of electricity usage quantity of the present month at premises 901, together with the aforementioned graph. Additionally, the monitor provides the display of the total figure of the electricity rate to the present date and the estimation value of the total figure of the electricity rate of the present month at premises 901.

Moreover, the tendency of the individual (or premises) related to electricity usage and advices are displayed on the monitor. The tendency corresponds to a message selected from a plurality of messages by server device 201 comparing the results between the previous month and the present month. The advice is a message selected from a plurality of messages by server device 201 comparing the unit price for premises 901 with the unit price for other premises 902, 903, 904, . . . .

By the configuration set forth above, the user of terminal device 101 can be given a comprehensive look at the total quantity of electricity usage quantity and total figure of the electricity rate for his/her premises 901, and the total quantity of electricity usage quantity and total figure of the electricity rate for the premises of other people. Particularly, since terminal device 101 can provide a comprehensive graph display as set forth above, the user of terminal device 101 can readily determine whether his/her unit price of the electricity rate is high or not as compared with other people. Moreover, the user of terminal device 101 can readily compare the unit price of the previous month with the unit price of the present month on premises 901 at terminal device 101.

Accordingly, the unit price of the electricity rate can be taken as an index to address saving-on in the quantity and cost of electricity. Thus, communication system 11 can offer the user of terminal device 101 (that is, the electricity contractor of premises 901) an incentive to suppress the electricity unit price. For example, by decreasing the unit price, the electricity rate can be lowered (saving-on money) even if the electricity usage quantity is the same as the previous month.

Since the electricity demand is lower during night hours than the day time, the nighttime electricity rate is lower than that of day time. By giving an incentive to reduce the unit price as set forth above, the user can be encouraged to use electricity more during the nighttime than during the day time. Eventually, the peak of the electricity demand during day time of the electric power company can be lowered.

Although description has been provided focusing on terminal device 101, a similar display is provided at other terminal devices 102-104.

### C. Hardware Configuration

c.1 Server Device

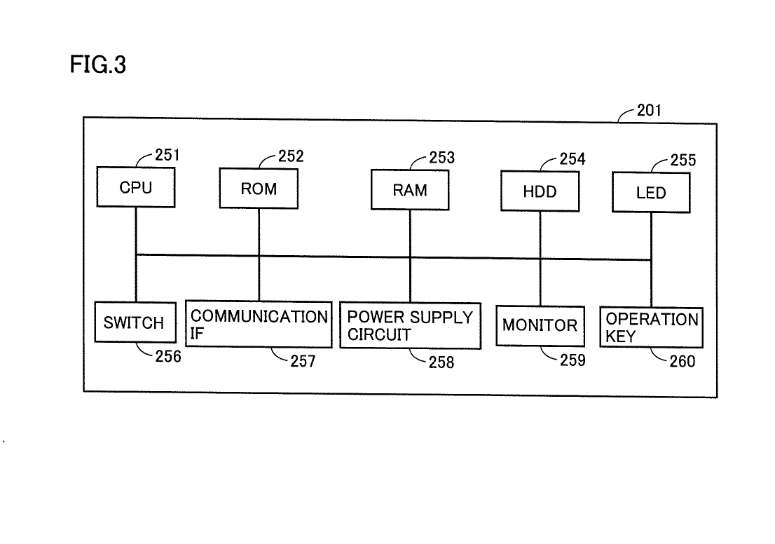

FIG. 3 represents a hardware configuration of server device 201. Referring to FIG. 3, server device 201 includes, as the main constituent elements, a CPU 251 executing a program, a ROM 252 storing data in a non-volatile manner, a RAM 253 storing, in a volatile manner, data generated by the execution of a program at CPU 251 or data input via an input device (not shown), an HDD 254 storing data in a non-volatile manner, an LED 255, a switch 256, a communication interface (IF) 257, a power supply circuit 258, a monitor 259, and an operation key 260. The constituent elements are all connected with each other through a data bus.

The process at server device 201 is implemented by each hardware and software executed by CPU 251. Such software may be prestored in HDD 254. The software may also be stored in another storage medium to be distributed as a program product. Alternatively, software may be provided as a downloadable program product from an information service provider connected on the Internet. Such software is read out from the storage medium by a reader, or downloaded via a communication IF or the like not shown to be temporarily stored in HDD 254. The software is read out from HDD 254 by CPU 251 to be stored in RAM 253 in the form of an executable program. CPU 251 executes the program.

Each of the constituent elements constituting server device 201 shown in FIG. 3 is a typical element. Therefore, it can be said that the essential part of the present invention is the software stored in RAM 253, HDD 254, and/or a storage medium, or downloadable via a network. Since the operation of hardware of server device 201 is well known, detailed description thereof will not be repeated here.

The recording medium is not limited to a DVD-RAM, and may be any medium that carries a program definitely such as a semiconductor memory including DVD-ROM, CD-ROM, FD, hard disk, magnetic tape, cassette tape, optical disk, EEPROM, flash ROM and the like. Moreover, the recording medium is a non-transitory medium that allows the computer to read out the relevant program and the like. As used herein, “program” includes not only a program that can be executed directly by a CPU, but also a program of the source program form, compression processed program, encrypted program, and the like.

c2. Terminal Device

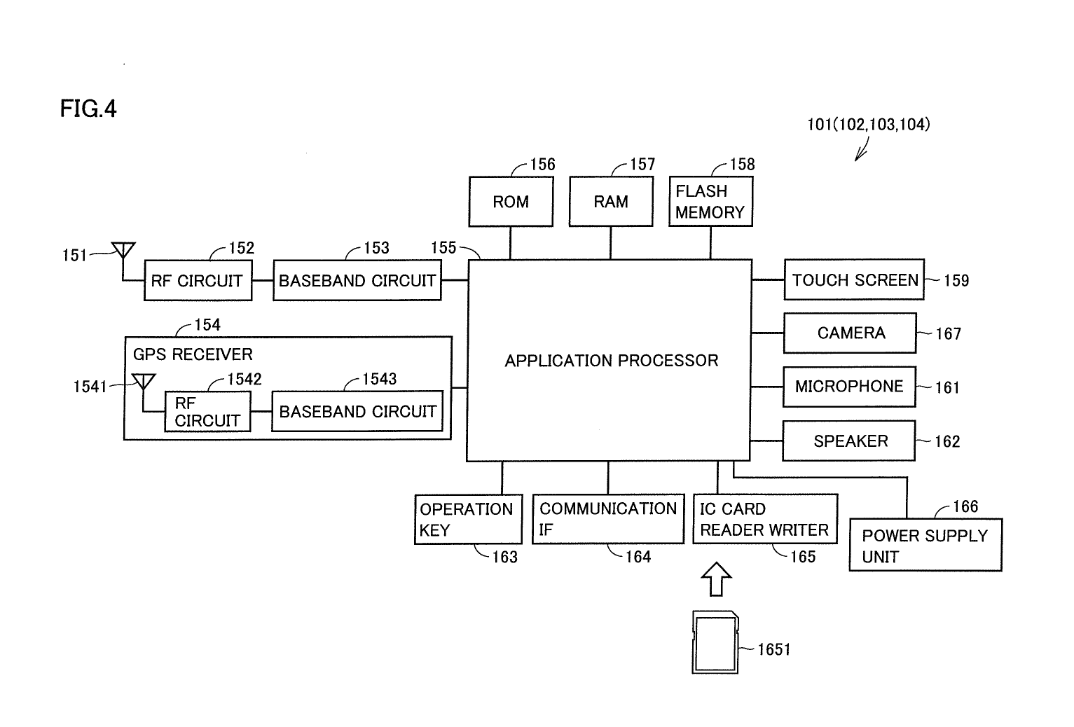

FIG. 4 represents a hardware configuration of terminal device 101. Referring to FIG. 4, terminal device 101 includes an antenna 151, a radio frequency (RF) circuit 152, a baseband circuit 153, a GPS receiver 154, an application processor 155 executing a program, a ROM (Read Only Memory) 156, a RAM (Random Access Memory) 157, a NAND type flash memory 158, a touch screen 159, a camera 167, a microphone 161, a speaker 162, an operation key 163 receiving an input of an instruction by a user, a communication interface (IF) 164, an IC (Integrated Circuit) card reader writer 165, and a power supply unit 166.

GPS receiver 154 includes an antenna 1541, an RF circuit 1542, and a baseband circuit 1543. GPS receiver 154 receives a signal from a GPS satellite by means of antenna 1541. GPS receiver 154 provides the processing results (current present location information) carried out at RF circuit 1542 and baseband circuit 1543 to application processor 155. The current location position information indicates the latitude, the longitude, and the altitude.

Antenna 151, RF circuit 152 and baseband circuit 153 are used in wireless communication with another mobile terminal, landline phone, or PC (Personal Computer) via a base station. Specifically, antenna 151, RF circuit 152 and baseband circuit 153 are used for the purpose of terminal device 101 carrying out communication through a mobile telephone network.

Flash memory 158 is a non-volatile semiconductor memory. Flash memory 158 stores, in a volatile manner, various types of programs to control terminal device 101, and various types of data such as data generated by terminal device 101 and data obtained from a device external to terminal device 101.

Each of constituent elements 153-159 and 161-167 is connected with each other through a data bus. A memory card 1651 will be attached to IC card reader writer 165.

The process at terminal device 10 is realized by each hardware and software executed by application processor 155. Such software may be prestored in flash memory 158. Further, software may be stored in another storage medium such as a memory card 1451 to be distributed as a program product. Alternatively, software may be provided as a downloadable program product from an information service provider connected on the Internet. Such software is read out from the storage medium by a reader such as IC card reader writer 165, or downloaded via antenna 151, RF circuit 152, and baseband circuit 153, or communication IF 164, and then temporarily stored in flash memory 158. That software is read out from flash memory 158 by application processor 155 to be stored in flash memory 158 in the form of an executable program. Application processor 155 executes that program.

Each constituent element constituting terminal device 101 in FIG. 4 is a typical one. Therefore, it can be said that the essential part of the present invention is the software stored in a recording medium such as flash memory 158 and memory card 1451, and/or downloadable via a network. Since the operation of hardware of terminal device 101 is well known, detailed description thereof will not be repeated here.

The recording medium is not limited to a DVD-RAM, a CD-ROM, an FD, or a hard disk, and may be any medium that stores a program statically such as a semiconductor memory including a magnetic tape, cassette tape, optical disk, optical card, EPROM, EEPROM, flash ROM and the like. Moreover, the recording medium is a non-transitory medium that allows the computer to read out the relevant program and the like. As used herein, “program” includes not only a program that can be executed directly by a CPU, but also a program of the source program form, compression processed program, encrypted program, and the like.

### D. Functional Configuration

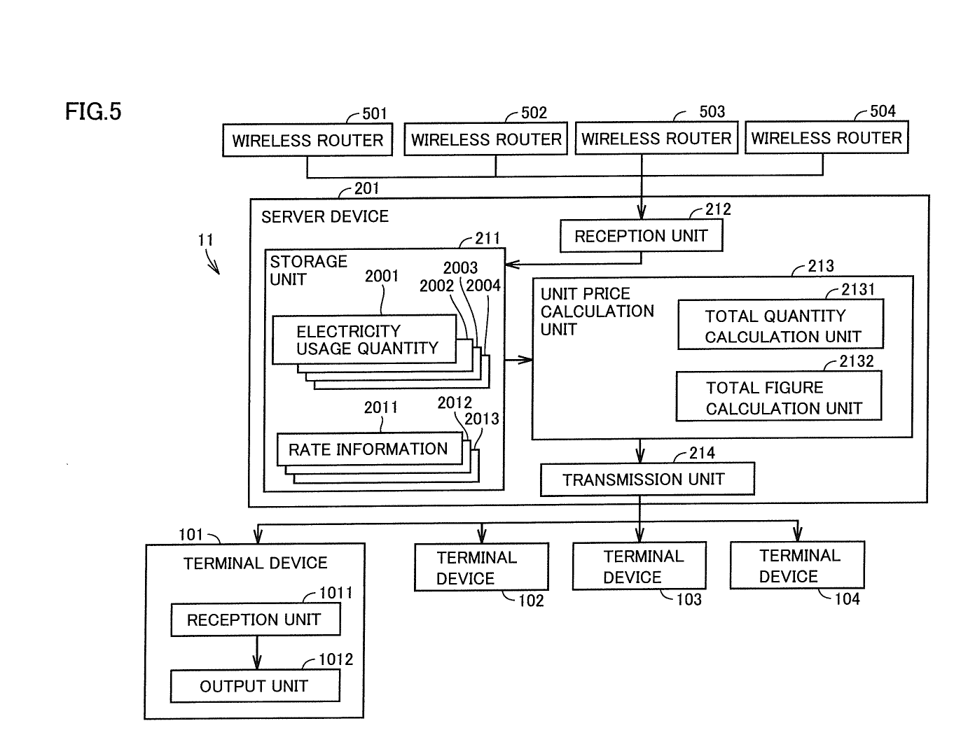

FIG. 5 is a diagram to describe a functional configuration of server device 201 and terminal device 101. Referring to FIG. 5, server device 201 includes a storage unit 211, a reception unit 212, a unit price calculation unit 213, and a transmission unit 214. Unit price calculation unit 213 includes a total quantity calculation unit 2131 and a total figure calculation unit 2132.

Storage unit 211 stores files 2011, 2012 and 2013 representing the rate information of a plurality of electric power companies. Each rate information further includes information of the charge based on a plurality of price systems of one electric power company. For example, file 2011 representing the rate information of an electric power company α includes a plurality of price plans α1, α2, α3, . . . . Storage unit 211 also stores which price plan of which electric power company is applied to each premises (that is for every contractor).

Reception unit 212 receives the electricity usage quantity by premises 901 from wireless router 501. Reception unit 212 also receives the electricity usage quantity by premises 902, 903 and 904 from wireless routers 502, 503 and 504, respectively. Each received electricity usage quantity is stored in storage unit 211 in correspondence with the time and date when the relevant electricity is used. For example, files 2001, 2002, 2003, 2004 . . . for storing the electricity usage quantity are created for every premises. In each file, the electricity usage quantity is stored, for example, in time series based on the aforementioned time and date. Thus, the electricity usage quantity sequentially received is sequentially stored in storage unit 211.

Unit price calculation unit 213 calculates the unit price of the electricity rate per unit electricity for each premises on a monthly basis, based on each electricity usage quantity and rate information. In the present embodiment, unit price calculation unit 213 calculates, by way of example, the unit price per 1 kWh of the present month and previous month. Details will be described hereinafter.

Total quantity calculation unit 2131 in unit price calculation unit 213 calculates the total quantity of electricity usage quantity by each premises for the present month and previous month based on each electricity usage quantity. For the present month, total quantity calculation unit 2131 calculates the total quantity of electricity usage quantity from the first day to the present day of the current month.

Total figure calculation unit 2132 in unit price calculation unit 213 calculates the total figure of the electricity rate of each premises for the present month and previous month based on each electricity usage quantity stored in correspondence with the aforementioned time and date, and the rate information. For the present month, total quantity calculation unit 2131 calculates the total figure of the electricity cost from the first day to the present day of the current month.

Unit price calculation unit 213 calculates the unit price of the electricity rate of the present month and previous month for each premises by dividing the total figure of the electricity rate for each premises by the total quantity of electricity usage quantity for each of the present month and previous month.

Transmission unit 214 responds to a request from each of terminal devices 101-104 to transmit at least information indicating the total figure of the electricity rate at each premises, information indicating the total quantity of electricity usage quantity, and information indicating the unit price of the electricity rate to terminal devices 101-104.

Specifically, transmission unit 214 transmits to terminal device 101 information about the total figure of the electricity rate, information about the total quantity of electricity usage quantity, and information about the unit price of each premises for the present month, and the information about the total figure of the electricity rate, information about the total quantity of electricity usage quantity, and information about the unit price for premises 901 of the previous month. In other words, transmission unit 214 transmits, not just the information of the present month, but also the information of the previous month, for the premises of the user of the terminal device.

Transmission unit 214 also transmits, as mentioned above, to each terminal device information about an estimation value of the total figure of electricity rate of the present month, an estimation value of the total quantity of electricity usage quantity of the present month, the tendency, advice, and the like. Calculation of the estimation value of the electricity rate total figure of the present month is performed by total figure calculation unit 2132. Calculation of the estimation value of the total quantity of electricity usage quantity of the present month is performed by total quantity calculation unit 2131.

Server device 201 may be configured to calculate the total quantity of electricity usage quantity, the total figure of the electricity rate, the unit price, and the like for a plurality of specified months including a month before the previous month, instead of just the present month and previous month.

Terminal device 101 includes a reception unit 1011, and an output unit 1012. Reception unit 1011 receives various information transmitted from server device 201. Output unit 1012 provides an output based on the received information. Output unit 1012 is configured including a monitor, for example, to display the image shown in FIG. 2 on the monitor. Output unit 1012 may be configured to notify each type of the received information audibly instead of visually.

Terminal devices 102, 103 and 104 have a functional configuration similar to that of terminal device 101. Therefore, description of the functional configuration of terminal devices 102, 103 and 104 will not be repeated here.

### E. Control Configuration

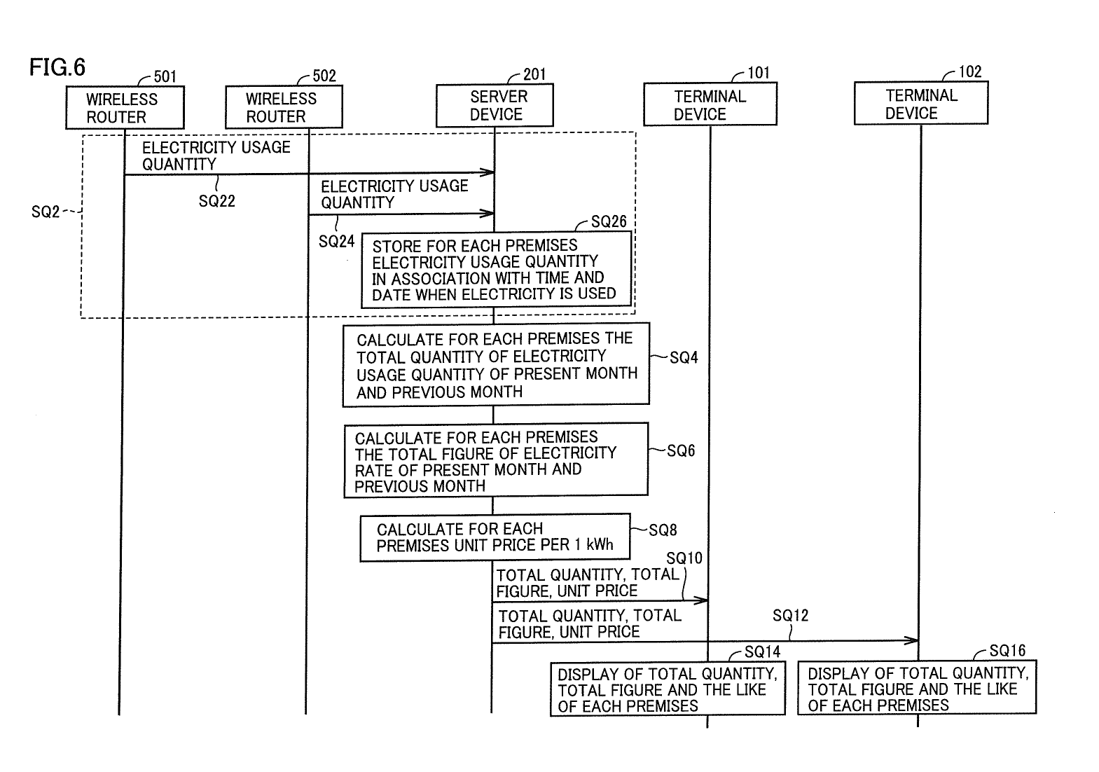

FIG. 6 is a sequence diagram to describe the process carried out at communication system 11. For the sake of convenience, only wireless routers 501 and 502 that are a part of the plurality of wireless routers are shown, and only terminal devices 101 and 102 that are a part of the plurality of terminal devices are shown In FIG. 6.

Referring to FIG. 6, sequence SQ2 includes sequences SQ22, SQ24, and SQ26. The process at sequence SQ2 is repeated until a trigger causing server device 202 to execute the process of sequence SQ4 is applied to server device 201.

At sequence SQ22, wireless router 501 transmits the electricity usage quantity by premises 901 to server device 201. The timing of transmission is not particularly limited. For example, the electricity usage quantity may be transmitted in real time, or at a predetermined time interval (for example, every one hour). In the case where the electricity usage quantity is transmitted at a predetermined time interval, the information of the time and date when the electricity is used is transmitted to server device 201 preferably in association with the electricity usage quantity. In this case, the time and date information can be taken in the unit of one hour, in the unit of one minute or in the unit of one second, for example.

At sequence SQ24, wireless router 502 transmits the electricity usage quantity by premises 902 to server device 201. The timing of transmission is similar to that of wireless router 501. Therefore, description thereof will not be repeated.

At sequence SQ26, server device 201 stores for every premises (every contractor) the electricity usage quantity by each premises in association with the time and date when the electricity is used. The time and date can be taken in the unit of one hour, in the unit of one minute or in the unit of one second, for example. The time and date may be any unit according to the price setting in the contract plan of the electric power company. For example, in the case where the price varies on an hourly basis, server device 201 should monitor the electricity usage quantity at least on an hourly basis.

At sequence SQ4, server device 201 calculates the total quantity of electricity usage quantity for the present month and previous month for every premises. At sequence SQ6, server device 201 calculates the total figure of the electricity rate of the present month and previous month for every premises. At SQ8, server device 201 calculates the unit price per 1 kWh for every premises and every month.

At sequence SQ10, server device 201 transmits to terminal device 101 information about the total quantity of electricity usage quantity of the present month, information about the total figure of the electricity rate of the present month and information about the unit price of the present month for each premises, and also information about the total quantity of electricity usage quantity of the previous month, information about the total figure of the electricity rate of the previous month and information about the unit price of the previous month for premises 901. At sequence SQ12, server device 201 transmits to terminal device 102, information about the total quantity of electricity usage quantity of the present month, information about the total figure of the electricity rate of the present month and information about the unit price of the present month for each premises, and also information about the total quantity of electricity usage quantity of the previous month, information about the total figure of the electricity rate of the previous month and information about the unit price of the previous month for premises 902.

At sequence SQ14, terminal device 101 displays the information received from server device 201 on the monitor. At sequence SQ16, terminal device 102 displays the information received from server device 201 on the monitor.

### Second Embodiment

In the present embodiment, another example of a communication system to cause a server device and terminal device to realize a process similar to that of the first embodiment will be described.

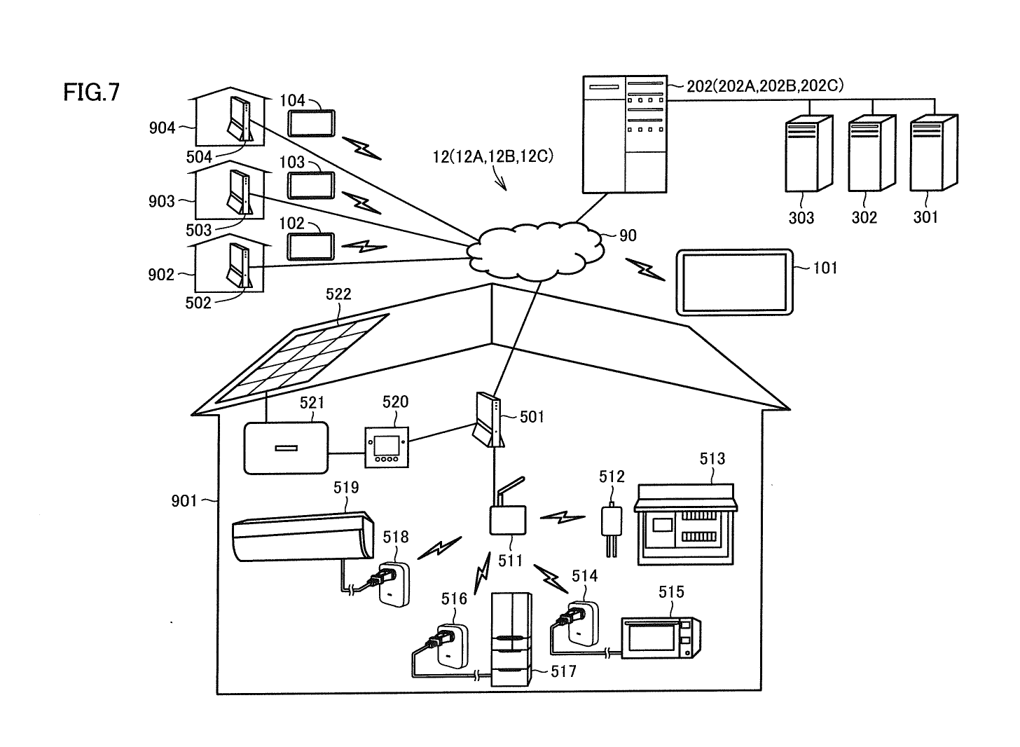

FIG. 7 is a schematic diagram of a system configuration of communication system 12 according to the present embodiment. Referring to FIG. 7, communication system 12 includes terminal devices 101-104, a server device 202, a plurality of server devices 301, 302 and 303, wireless routers 501-504, a relay 511, a CT sensor 512, a distribution board 513, electric power consumption measurement devices 514, 516, and 518 called SMART TAP (registered trademark), a microwave oven 515, a refrigerator 517, an air conditioner 519, a display device 520, a power conditioner 521, and a solar panel 522.

Electric power consumption measurement device 514 is connected to microwave oven 515. Electric power consumption measurement device 514 transmits the electricity usage quantity (the amount of consumed electric power) at microwave oven 515 to relay 511. Electric power consumption measurement device 516 is connected to refrigerator 517 to transmit the electricity usage quantity at refrigerator 517 to relay 511. Electric power consumption measurement device 518 is connected to air conditioner 519 to transmit the electricity usage quantity at air conditioner 519 to relay 511. Relay 511 transmits to wireless router 501 the electricity usage quantity received from each electric power consumption measurement device. Wireless router 501 transmits the electricity usage quantity of each household appliance received from relay 511 to server device 202 via network 90.

Solar panel 522 is connected to power conditioner 521, which is connected to display device 520. Display device 520 is connected to wireless router 501. Display device 520 displays various information such as the amount of power generated at solar panel 522, the amount of purchased power, the amount of sold power and the like. The amount of purchased power and the amount of sold power are transmitted to server device 202 via wireless router 501.

Server devices 301, 302 and 303 are communicatably connected to server device 202. Server device 301 is the server device of electric power company α. Server device 302 is the server device of electric power company β. Server device 303 is the server device of a weather forecast service company.

Server device 202 performs a process basically similar to that of server device 201 of the first embodiment, and has a functional configuration basically similar to that of server device 201. Further, the hardware configuration of server device 202 is similar to that of server device 201. Mainly, the function of server device 202 differing from that of server device 201 will be described hereinafter.

Server device 202 receives a plurality of price plans of the electricity contract of electric power company α from server device 301 and stores the same in storage unit 211 as a file 2011. Server device 202 also receives a plurality of price plans of the electricity contract of electric power company β from server device 302 and stores the same in storage unit 211 as a file 2012.

Server device 202 obtains and stores in storage unit 211 external information such as the weather and temperature from server device 303. Server device 202 transmits various information utilizing the relevant external information to terminal devices 101-104.

Further, server device 202 obtains through each wireless router information such as environmental information of each premises (for example, indoor temperature, indoor humidity, illumination intensity of a room) and stores the relevant environmental information into storage unit 211 in association with each premises and the time and date. Examples of using such external information will be described afterwards in another embodiment.

Although a configuration has been described in which server device 202 obtains the price plan from server devices 301 and 302 of electric power companies, server device 202 may obtain information other than the price plan. For example, server device 202 may obtain electricity suppression information from server devices 301 and 302. Server device 202 may also obtain train running information, traffic congestion, sales information, information from the local community and the like. Moreover, server device 202 may obtain via each wireless router the usage history of each household appliance installed at the premises.

### Third Embodiment

In the present embodiment, another example of a communication system to cause a server device and terminal device to implement a process similar to that of the first embodiment will be described hereinafter.

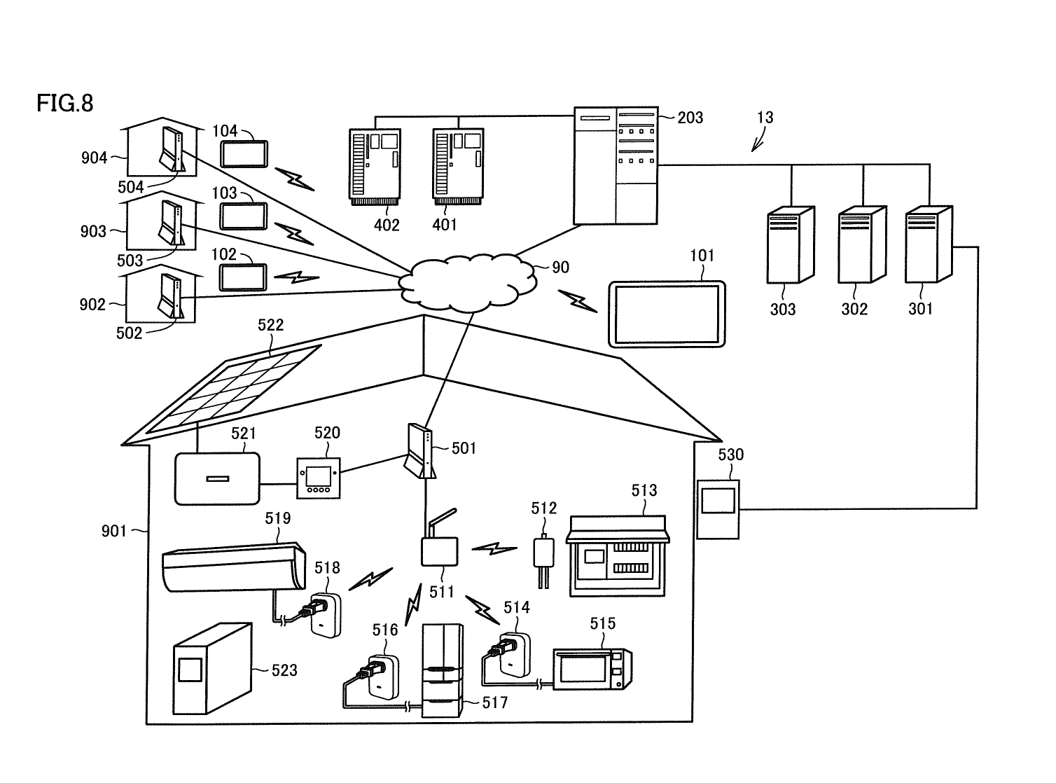

FIG. 8 is a schematic diagram of a system configuration of a communication system 13 according to the present embodiment. Referring to FIG. 8, communication system 13 includes terminal devices 101-104, a server device 203, a plurality of server devices 301, 302 and 303, a plurality of server devices 401 and 402, wireless routers 501-504, a relay 511, a CT sensor 512, a distribution board 513, electric power consumption measurement devices 514, 516 and 518, a microwave oven 515, a refrigerator 517, an air conditioner 519, a display device 520, a power conditioner 521, a solar panel 522, a storage battery 523, a SMART METER (registered trademark) and an electricity meter 530. In other words, communication system 13 differs from communication system 12 of the second embodiment in the inclusion of server devices 401 and 402, storage battery 523, and electricity meter 530.

Server device 203 performs a process basically similar to that of server device 202 of the second embodiment, and has a functional configuration basically similar to that of server device 202. Further, the hardware configuration of server device 203 is similar to that of server devices 201 and 202. Therefore, mainly the function of server device 203 differing from that of server devices 201 and 202 will be described hereinafter.

Server devices 401 and 402 are communicatably connected to server device 203. Server device 301 is the server device of a communication service organization. Server device 302 is the server device of a game organization.

Server device 203 obtains and stores in storage unit 211 communication information (contents of a chat, the contents of transfer in an SNS (social networking service) and the like) from server device 401. Server device 203 transmits various information utilizing the relevant information to terminal devices 101-104. Server device 203 obtains and stores into storage unit 211 a program such as a game from server device 402. Server device 203 transmits the relevant program to terminal devices 101-104 in response to a request therefrom.

### Fourth Embodiment

In the present embodiment, a configuration utilizing communication system 11 (FIG. 1) described in the first embodiment will be described (first usage example). For the sake of convenience, the communication system in the present embodiment is referred to as “communication system 11A” and the server device in communication system 11A is referred to as a server device 201A, as represented in parentheses in FIG. 1.

Server device 201A provides a ranking on a monthly basis in the order of a lower unit price based on the information of the unit price calculated for each premises. Server device 201A transmits to each terminal device the contractor identification information and unit price information from the first ranking to a specified ranking (for example, up to the third place). Server device 201A also transmits ranking information representing the ranking of the unit price for the premises of the user of the terminal device. For example, server device 201A transmits to terminal device 101 ranking information representing the ranking of the unit price for premises 901.

Each terminal device receives from server device 201A the contractor identification information and unit price information for the first ranking to the specified ranking, and the ranking of the unit price of premises 901 (in other words, the ranking of the user of terminal device 101 and the contractor of premises 901).

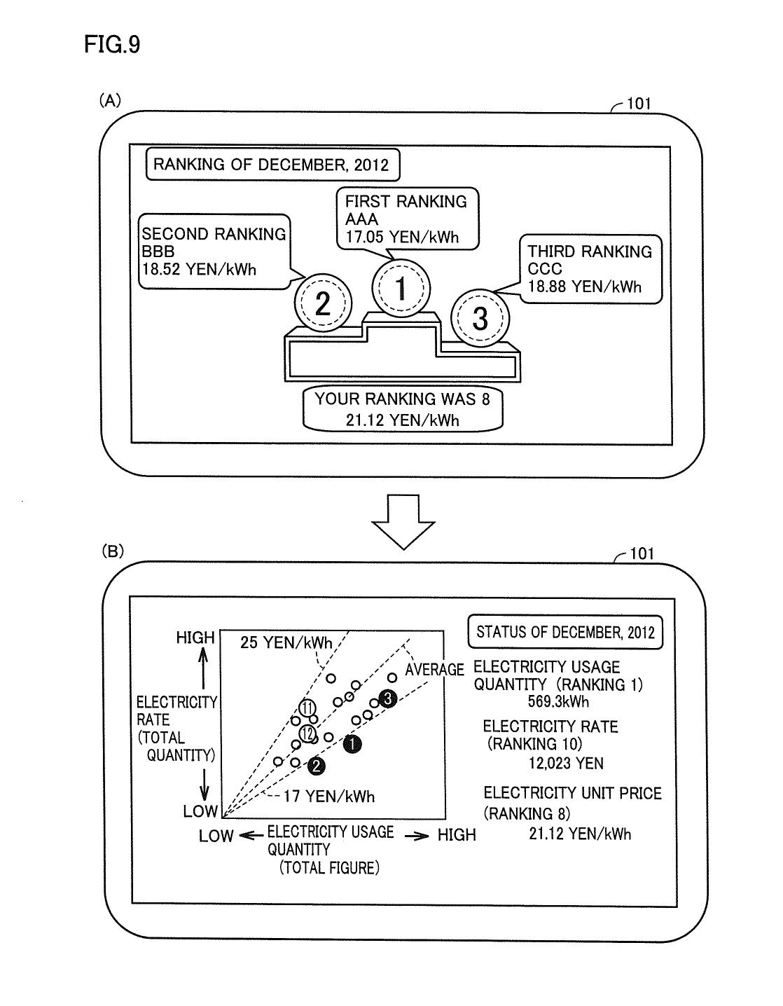

FIG. 9 is a diagram to represent an image displayed at terminal device 101. FIG. 9 (A) represents an example of an image representing the ranking of the unit price. FIG. 9 (B) represents an example of an image after transition when a predetermined instruction is applied to terminal device 101 at the state of FIG. 9 (A).

Referring to FIG. 9 (A), terminal device 101 displays the information on the unit price from the first ranking to the third ranking that is the specified ranking and ID information of the contractor in correspondence. Terminal device 101 displays the ranking of the unit price of premises 901 (for example, eighth ranking), and unit price information (for example 21.12 yen/kWh). The user of terminal device 101 can readily recognize his/her ranking and the difference in the unit price from the user of an upper ranking by looking at the image shown in FIG. 9 (A).

Referring to FIG. 9 (B), terminal device 101 displays a graph with the total quantity of electricity usage quantity plotted along the horizontal axis and the total figure of the electricity rate plotted along the vertical axis, as described in association with FIG. 2. Specifically, terminal device 101 inserts “1”, “2” and “3” representing the ranking into the circles corresponding to the unit price from the first ranking to the third ranking. In this case, terminal device 101 displays the numbers “1”, “2” and “3” in open characters in order to discriminate from the numbers representing the present month and previous month for premises 901 of the user of terminal device 101. The display of the graph shown in FIG. 9 (B) by terminal device 101 allows the user of terminal device 101 to recognize the difference in the unit price from the user of an upper ranking more clearly.

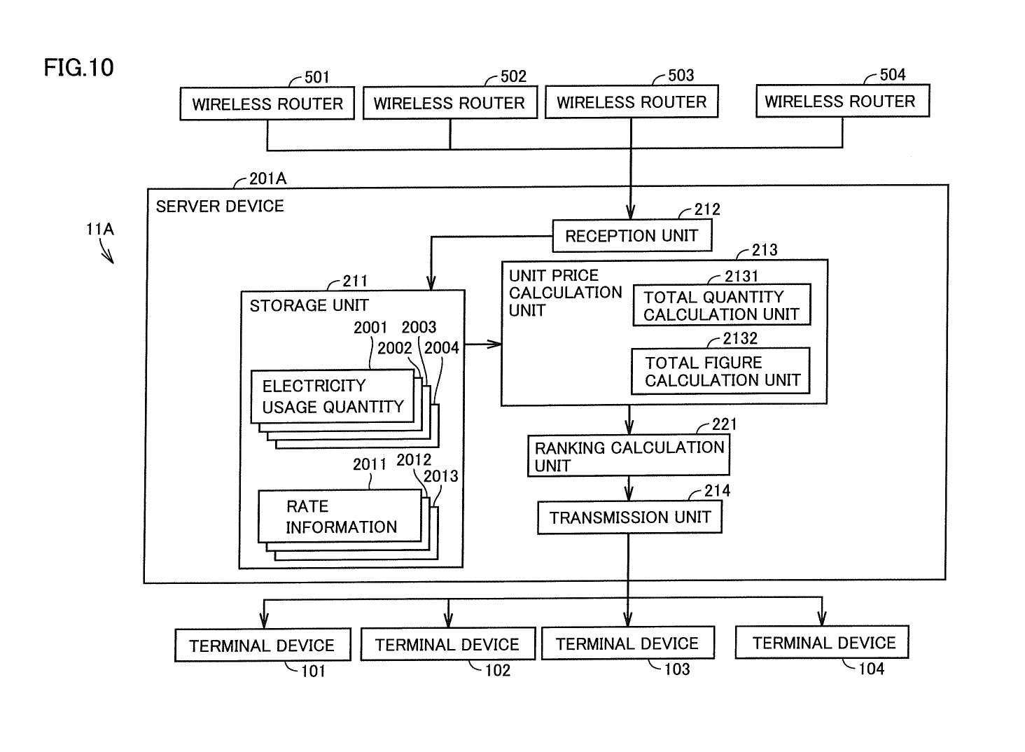

FIG. 10 is a diagram to describe the functional configuration of server device 201A. Referring to FIG. 10, server device 201A includes a storage unit 211, a reception unit 212, a unit price calculation unit 213, a transmission unit 214, and a ranking calculation unit 221. Server device 201A differs from server device 201 of the first embodiment in the inclusion of ranking calculation unit 221.

Based on the information of the unit price calculated for each premises, ranking calculation unit 221 accords the ranking on a monthly basis of the unit price in the order of a lower price. Ranking calculation unit 221 transmits the contractor ID information and unit price information for the ranking of the present month from the first ranking to the specified ranking, for example, to transmission unit 214. Ranking calculation unit 221 also transmits to transmission unit 214 the ranking information representing the ranking of the unit price of the premises of the user of the terminal device requesting transmission of ranking information (for example, premises 901 when terminal device 101 is relevant).

Transmission unit 214 transmits the information received from ranking calculation unit 221 together with various information of the interest of transmission (total quantity of electricity usage quantity, total figure of the electricity rate, unit price and the like) further to the terminal device from which transmission of ranking information was requested.

Each of the above-described process at communication system 11A can be realized using communication system 12 described in the second embodiment or communication system 13 described in the third embodiment.

### Fifth Embodiment

In the present embodiment, a process that can be executed further by utilizing communication system 12 described in the second embodiment (second usage example) will be described.

Terminal device 101 receives from server device 202 ratio information representing the ratio of the electricity rate of each household appliance to the total figure of the electricity rate of the previous month and to the estimation value of the total figure of the electricity rate of the present month for premises 901. Similarly, terminal devices 102, 103 and 104 receive from server device 202 the aforementioned ratio information on the present month and previous month for premises 902, 903 and 904, respectively. Terminal devices 101-104 provide a screen display based on the received ratio information.

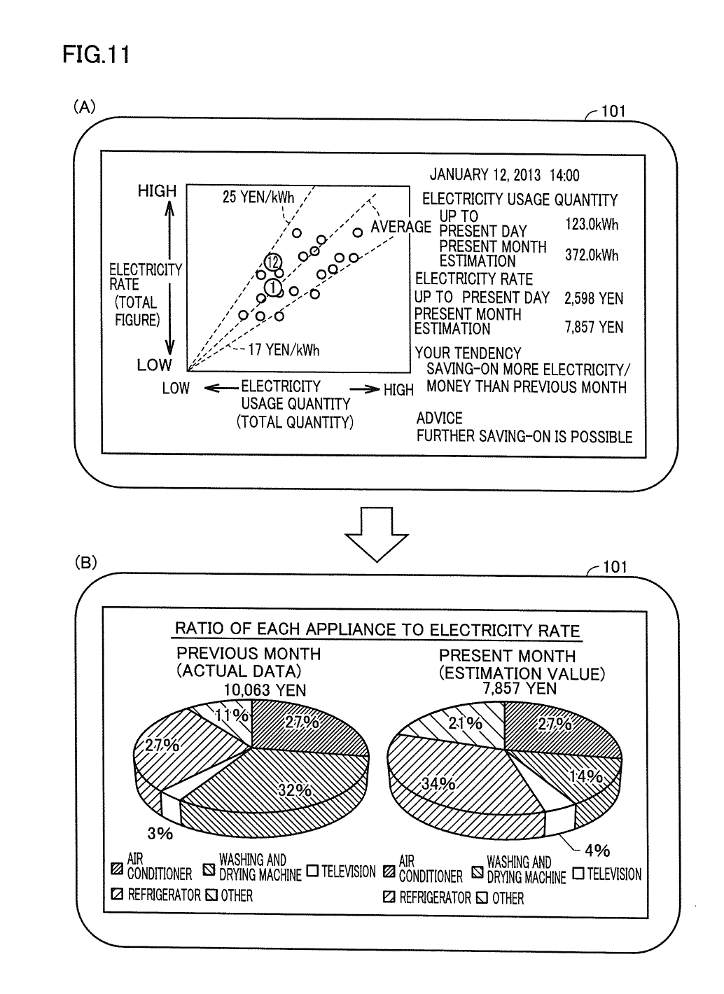

FIG. 11 is a diagram to describe a screen display based on ratio information at terminal device 101. FIG. 11 (A) is the same image as FIG. 2. FIG. 11 (B) represents an image subsequent to transition when a predetermined instruction is applied to terminal device 101 at the state of FIG. 11 (A). Specifically, FIG. 11 (B) represents a screen display based on ratio information. Since FIG. 11 (A) is the same as FIG. 2 described above, description thereof will not be repeated here.

Referring to FIG. 11 (B), terminal device 101 displays the ratio of the electricity rate of each household appliance to the total figure of the electricity rate of the previous month using a graph at a predetermined region (the left side region) in the screen. Terminal device 101 also displays the total figure of the electricity rate (actual data) in the proximity of the graph. In addition, terminal device 101 displays the ratio of the electricity rate of each household appliance to the estimation value of the total figure of the electricity rate of the present month using a graph at a predetermined region (the right side region) in the screen. Further, terminal device 101 displays the estimation value of the total figure of the electricity rate in the proximity of the graph.

By terminal device 101 providing the display shown in FIG. 11 (B), the user of terminal device 101 can confirm the estimation value of the electricity rate of the present month and the total figure of the electricity rate of the previous month in comparison. Moreover, the user can identify the household appliance that exhibits a higher usage among the plurality of household appliances, as compared to the previous month. Therefore, by suppressing the usage of the household appliance exhibiting a higher usage frequency, the user can reduce the total figure of the electricity rate and the total quantity of electricity usage quantity of the present month for premises 901.

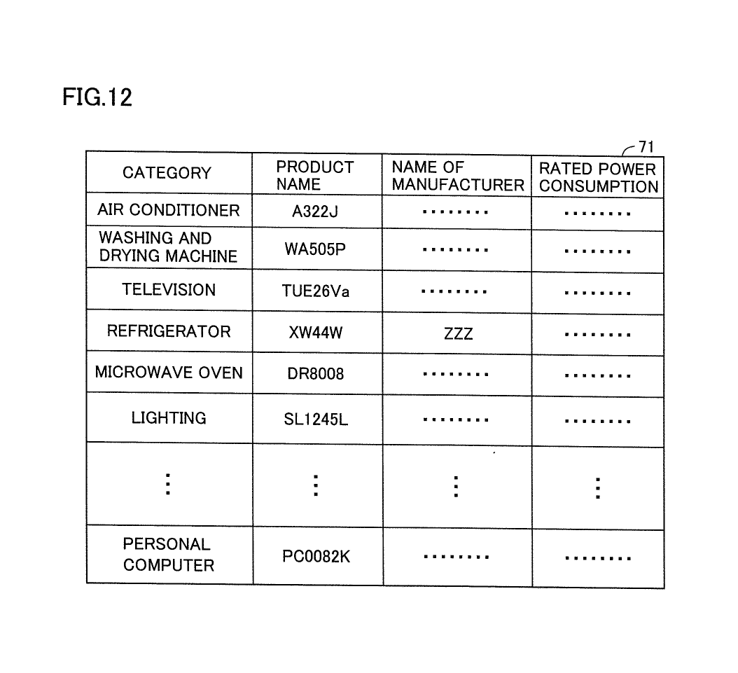

FIG. 12 is a diagram to describe a data table 71 stored in storage unit 211 of server device 202. Referring to FIG. 12, data table 71 has the product name of each household appliance, the category of the household appliance, the rated power consumption, and the name of a manufacturer in correspondence. For example, the product shown in data table 71 is a product of an organization providing the service at server device 202, or a product of a company related to the relevant organization. Since a household appliance of a newer type is generally directed to saving-on more power as compared to a conventional household appliance, the name of a household appliance of a newer type is preferable for the product name. The product shown in data table 71 may be one of an organization not related to the organization possessing server device 202.

Server device 202 has the product name and rated power consumption of a household appliance used at each premises stored. Server device 202 calculates the estimation value of the total figure of the electricity rate for a household appliance having a higher ratio among the estimation values of the present month in the case where that household appliance is replaced by purchase with a household appliance disclosed in data table 71. Further, server device 202 calculates the money that can be saved in the case where the household appliance is replaced by purchase. Further, server device 202 calculates the ratio of the electricity rate for each household appliance to the estimation value of the total figure of the electricity rate of the present month in the case where the household appliance is replaced by purchase.

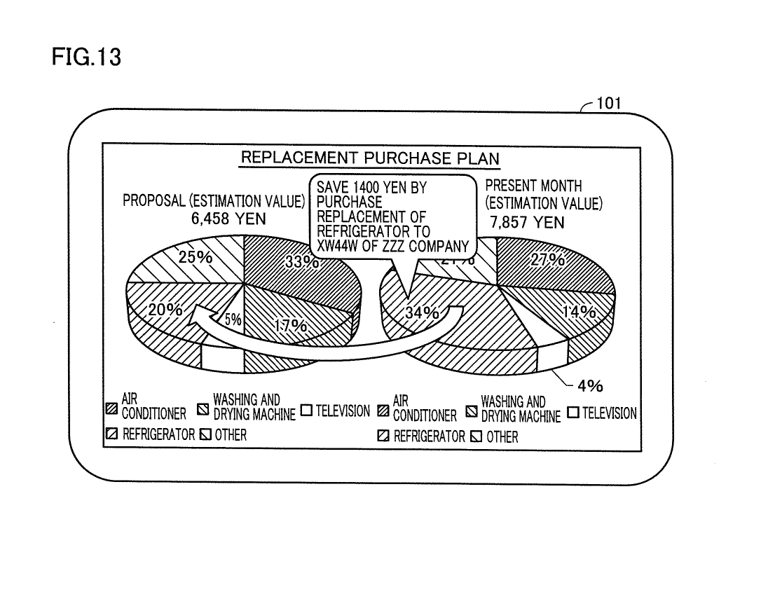

Terminal device 101 receives from server device 202 ratio information representing the ratio of the electricity rate for each household appliance to the estimation value of the total figure of the electricity rate of the present month. Terminal device 101 also receives from server device 202 information about the estimation value of the total figure of the electricity rate, information about the money that can be saved, and ratio information indicating the calculated ratio in the case where the household appliance is replaced by purchase. Terminal device 101 provides a screen display based on each received information (FIG. 13). A process similar to that of terminal device 101 is also carried out at terminal devices 102, 103 and 104.

FIG. 13 represents an image subsequent to transition when a predetermined instruction is applied to terminal device 101 at the state of FIG. 11 (B). Specifically, FIG. 13 represents a screen display based on the information generated by server device 202 utilizing data table 71.

Referring to FIG. 13, terminal device 101 displays the ratio of the electricity rate of each household appliance to the estimation value of the total figure of the electricity rate of the present month using a graph at a predetermined region (the right side region) in the screen. Terminal device 101 also displays the estimation value of the total figure of the electricity rate in the proximity of the graph. In addition, terminal device 101 displays the ratio of the electricity rate of each household appliance to the estimation value of the total figure of the electricity rate of the present month in the case where that household appliance is replaced by purchase using a graph at a predetermined region (the left side region) in the screen. Further, terminal device 101 displays the estimation value of the total figure of the electricity rate in the case where that household appliance is replaced by purchase in the proximity of the graph. Terminal device 101 displays, at the middle of the screen, the product name of which purchase is recommended and the name of the manufacturer of the relevant product, together with the amount of money that can be saved.

The user of terminal device 101 can accept the proposal to make a replacement purchase of a household appliance that can realize energy savings by terminal device 101 displaying the screen shown in FIG. 13.

In the case where the manufacturer of the household appliance of which replacement is recommended and the company providing the service at server device 202 are the same organization, sales promotion of a household appliance of its own organization can be made to the user of terminal device 101. In the case where the manufacturer of the household appliance of which replacement purchase is recommended and the company providing the service at server device 202 is not the same organization or not the same related organization, the organization providing the service at server device 202 can earn a profit from the manufacturer producing the household appliance of which replacement purchase is recommended by providing a replacement purchase proposal shown in FIG. 13.

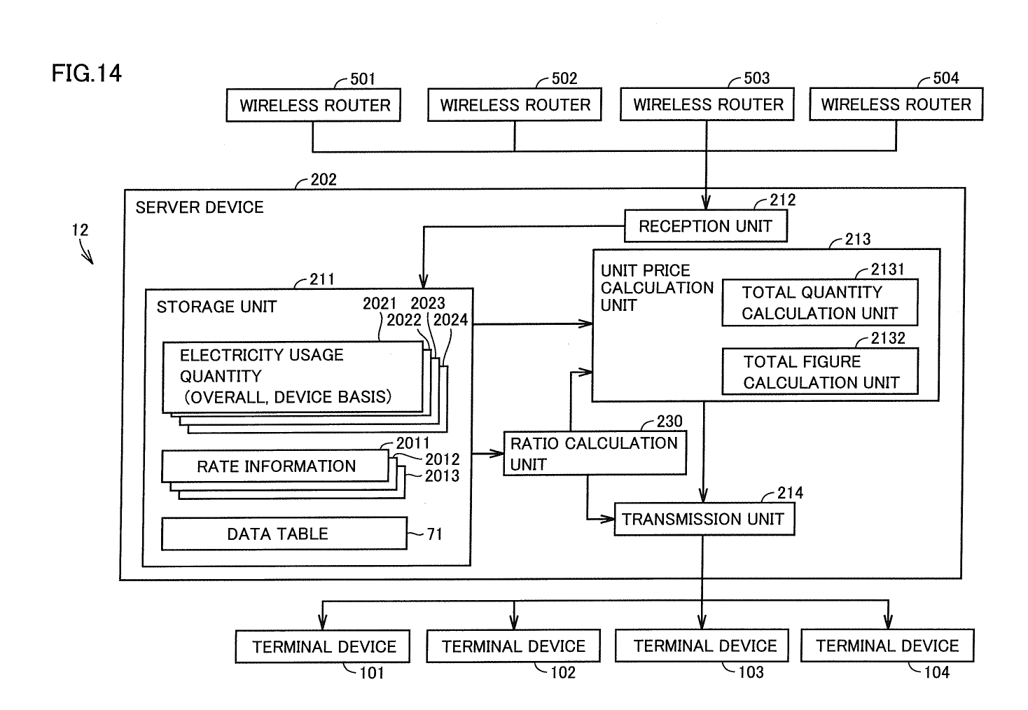

FIG. 14 is a diagram to describe a functional configuration of server device 202. Referring to FIG. 14, server device 202 includes a storage unit 211, a reception unit 212, a unit price calculation unit 213, a transmission unit 214, and a ratio calculation unit 230. In other words, server device 202 differs from server device 201 of the first embodiment in the inclusion of ratio calculation unit 230.

Storage unit 211 stores files 2021, 2022, 2023, 2024, . . . instead of files 2001, 2002, 2003, 2004, . . . , respectively, for storing the electricity usage quantity. In file 2021, there are stored, in time series, the entire electricity usage quantity on premises 901 and the electricity usage quantity of each household appliance installed on premises 901 based on the date and time. Files 2022, 2023 and 2024 store, in time series, the entire electricity usage quantity on premises 902, 903 and 904 and the electricity usage quantity of each household appliance installed on premises 902, 903 and 904, respectively.

Storage unit 211 further stores data table 71 as well as data indicating the product name of each household appliance used at each premises and the rated power consumption at each premises (not shown).

Ratio calculation unit 230 calculates for each premises the ratio of the electricity rate of each household appliance to the total figure of the electricity rate of the previous month and to the estimation value of the total figure of the electricity rate of the present month. Further, ratio calculation unit 230 calculates the ratio of the electricity rate of each household appliance to the estimation value of the total figure of the electricity rate of the present month in the case where the household appliance is replaced by purchase. Ratio calculation unit 230 sends the calculated ratio to transmission unit 214. In this case, server device 202 calculates the money that can be saved by purchase replacement, and the total figure of the electricity rate in the case where replacement by purchase is conducted.

Transmission unit 214 also transmits information received from ratio calculation unit 230, information representing the money that can be saved by the purchase replacement, and information of the total figure of the electricity rate in the case where purchase replacement is conducted, together with various information of the transmission of interest set forth above (total quantity of electricity usage quantity, total figure of the electricity rate, unit price and the like) to the terminal device from which transmission of ratio information has been requested.

Server device 202 may be configured to calculate an estimation value of the present month unit price of the electricity rate in the case where purchase replacement is conducted, and transmit the calculated estimation value to the terminal device from which transmission of ratio information is requested.

Each process set forth above can be realized by utilizing communication system 13 described in the third embodiment.

### Sixth Embodiment

In the present embodiment, a configuration utilizing communication system 12 (FIG. 7) described in the second embodiment will be described (third usage example). For the sake of convenience, the communication system in the present embodiment is referred to as “communication system 12A” and the server device in communication system 12A is referred to as a server device 202A, as represented in parentheses in FIG. 7. In the present embodiment, a system configuration allowing provision of an electricity saving-on advice based on the unit price of the electricity rate to the user of the terminal device will be described.

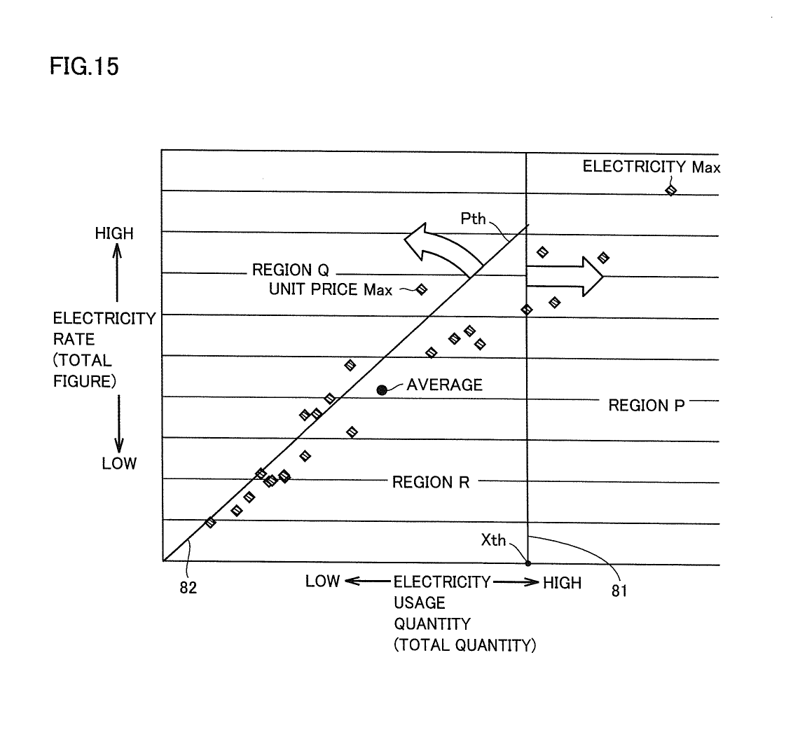

FIG. 15 is a visual representation in the form of a graph of the total quantity of electricity usage quantity of the present month, the total figure of the electricity rate of the present month, and the unit price of the present month for each premises, stored in server device 202A. Referring to FIG. 15, each point in the graph (hereinafter, also referred to as “plot”) represents the total quantity of electricity usage quantity, the total figure of the electricity rate, and the unit price for the premises.

The plot indicated as “electricity MAX” corresponds to the maximum of the total quantity of electricity usage quantity of all plots. The plot indicated as “unit price MAX” corresponds the maximum of the unit price of all plots. The plot indicated as “average” represents the average value of all plots.

Boundary line 81 relates to the total quantity of electricity usage quantity, and is parallel to the vertical axis. Boundary line 81 is defined by a threshold value Xth of the total quantity of electricity usage quantity. The region at the right side of boundary line 81 is referred to as “region P”.

Boundary line 82 relates to the unit price of the electricity rate, which is defined by a threshold value Pth of the unit price. The region upper than boundary line 82, excluding region P, is referred to as “region Q”. The region lower than boundary line 82, excluding region P, is referred to as “region R”.

Server device 202A selects a different message depending upon whether the plot is located at region P, located at region Q, or located at region R. The message includes the tendency and advice.

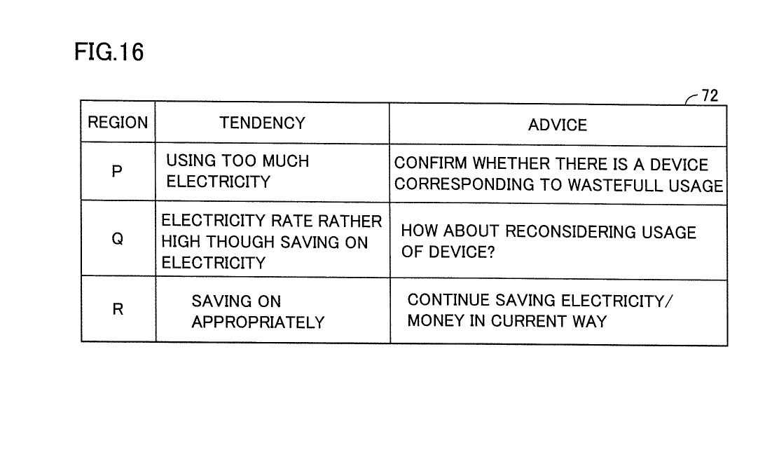

FIG. 16 represents a data table 72 indicating the tendency and advice. Referring to FIG. 16, a tendency differing in contents from each other, and an advice differing in contents from each other, are provided for each of regions P, Q and R.

For region P, a message prompting saving-on electricity (tendency and advice) is provided in correspondence. For region Q, a message prompting saving-on money is provided in correspondence. For region R, a message assuring the savings on electricity and money is provided in correspondence.

Server device 202A refers to data table 72 to read out the tendency and advice from the region corresponding to the plot for each premises, and notifies the terminal device of the user that is the contractor of the relevant premises about the tendency and advice read out.

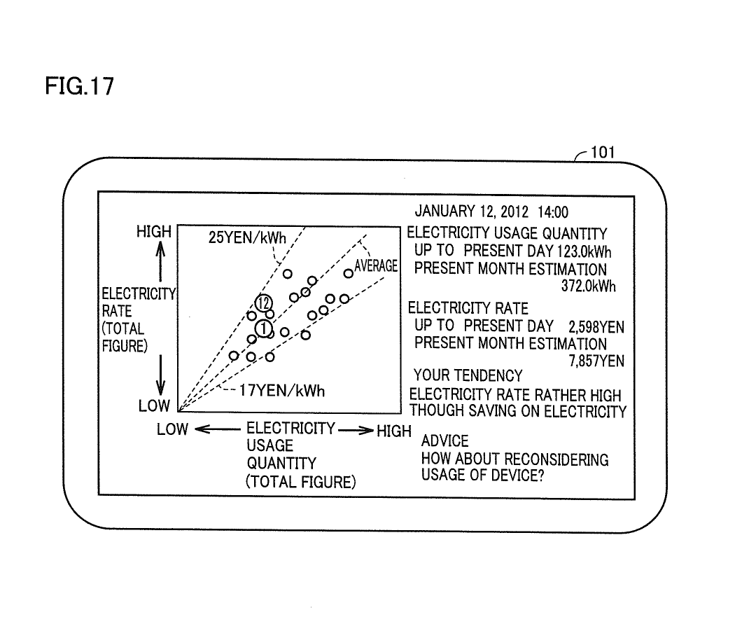

FIG. 17 represents an image displayed at terminal device 101 when the plot for premises 901 is located at region Q. Referring to FIG. 17, terminal device 101 displays the graph shown in FIG. 2 together with the tendency and advice corresponding to region Q in data table 72.

As mentioned above, region Q and region R are partitioned by the unit price. Therefore, notification of a message according to the unit price can be realized for the user of terminal device at communication system 12A.

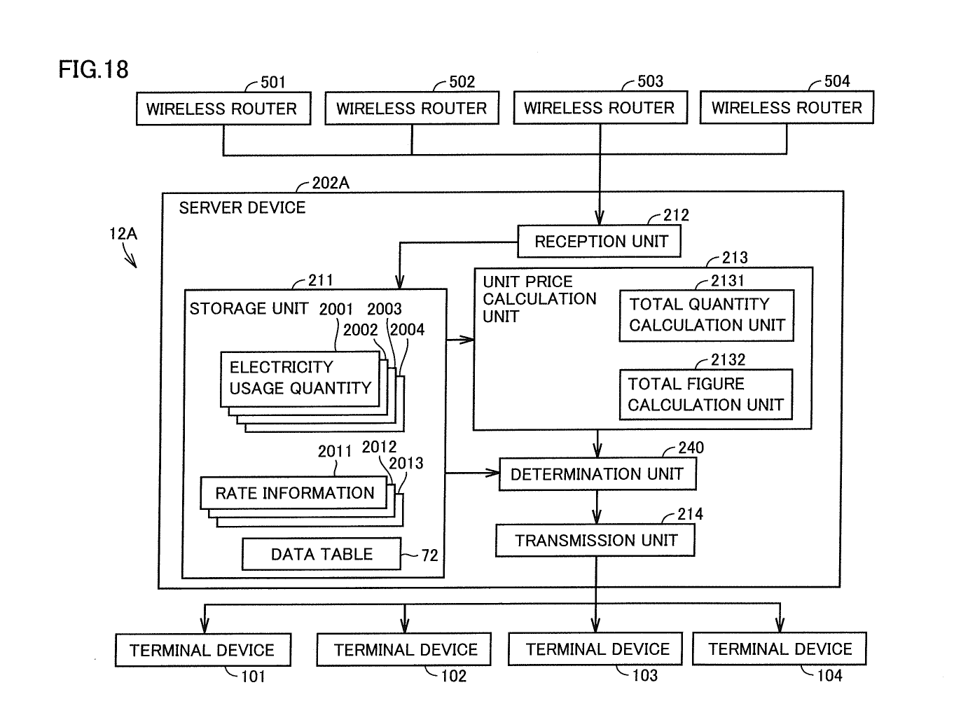

FIG. 18 is a diagram to describe the functional configuration of server device 202A. Referring to FIG. 18, server device 202A includes a storage unit 211, a reception unit 212, a unit price calculation unit 213, a transmission unit 214, and a determination unit 240. In other words, server device 202A differs from server device 201 according to the first embodiment in the inclusion of determination unit 240.

Storage unit 211 further includes a data table 72.

Determination unit 240 determines whether the total quantity of electricity usage quantity is greater than or equal to threshold value Xth for each plot. Determination unit 240 also determines whether the unit price of the electricity rate is greater than or equal to a threshold value Pth for each plot. Determination unit 240 selects one message from the three messages (tendency and advice) in data table 72 based on the unit price and the total quantity of electricity usage quantity for each terminal device. Determination unit 240 transmits the selected message to transmission unit 214.

Transmission unit 214 sends the message transmitted from determination unit 240 to the terminal device from which transmission of information has been requested, together with various information of the interest of transmission set forth above (total quantity of electricity usage quantity, total figure of the electricity rate, unit price and the like).

Calculation of boundary line 81 and boundary line 82 will be described hereinafter. In other words, calculation of the value of the total quantity of electricity usage quantity defining boundary line 81 (threshold value Xth) and the inclination of boundary line 82 (threshold value Pth) will be described.

Server device 202A obtains Xth by, for example, equation (1) set forth below. Server device 202A obtains Pth by, for example, equation (2) set forth below.

Xth=X(AVE)+(X(max)−X(AVE))×0.5 (1)

Pth=P(AVE)−(P(max)−P(AVE))×0.5 (2)

In equation (1), X(AVE) is the average of the total quantity of electricity usage quantity over all the plots. X(max) is the maximum value of the total quantity of electricity usage quantity. In other words, X(max) is the total quantity of electricity usage quantity in the plot with the indication of electricity MAX.

In equation (2) P(AVE) is the average value of the unit price over all the plots. P(max) is the maximum value of the unit price. In other words, P(max) is the unit price per se for the plot with the indication of unit price MAX.

### Seventh Embodiment

Another configuration utilizing communication system 12 (FIG. 7) described in the second embodiment (fourth usage example) will be set forth below. For the sake of convenience, the communication system in the present embodiment is referred to as “communication system 12B” and the server device in communication system 12B is referred to as a server device 202B, as represented in parentheses in FIG. 7.

Terminal device 101 receives from server device 202B the electricity rate, information about the outside temperature around premises 901 (or the district where premises 901 is located), information about the indoor temperature at premises 901, information about the weather of the district where premises 901 is located, and unit price information on a daily basis of the month specified by the user (for example, the present month). Terminal device 101 displays the received information on the monitor. A process similar to that of terminal device 101 is performed at terminal devices 102-104.

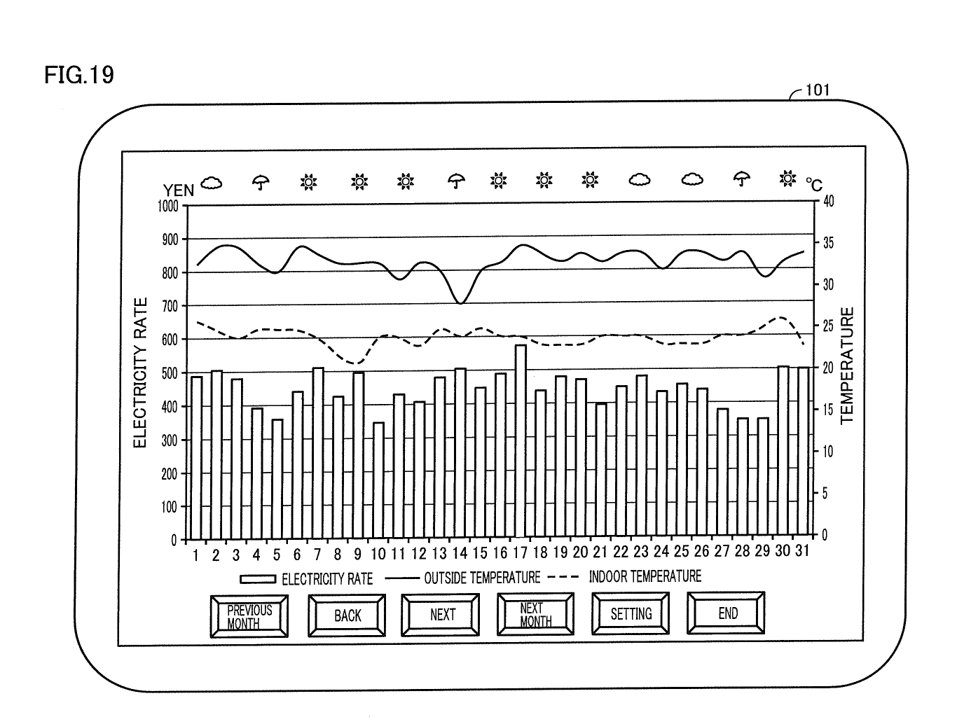

FIG. 19 represents a display screen of terminal device 101. Referring to FIG. 19, terminal device 101 displays the electricity rate, outside temperature, indoor temperature, weather information on a daily basis in a graph based on the information received from server device 202B. The user of terminal device 101 can look at the graph shown in FIG. 19 to identify how the electricity rate is changing according to the weather, outside temperature, and indoor temperature. For the sake of convenience, FIG. 19 shows a display of the weather information for every several days. However, the display is not limited thereto.

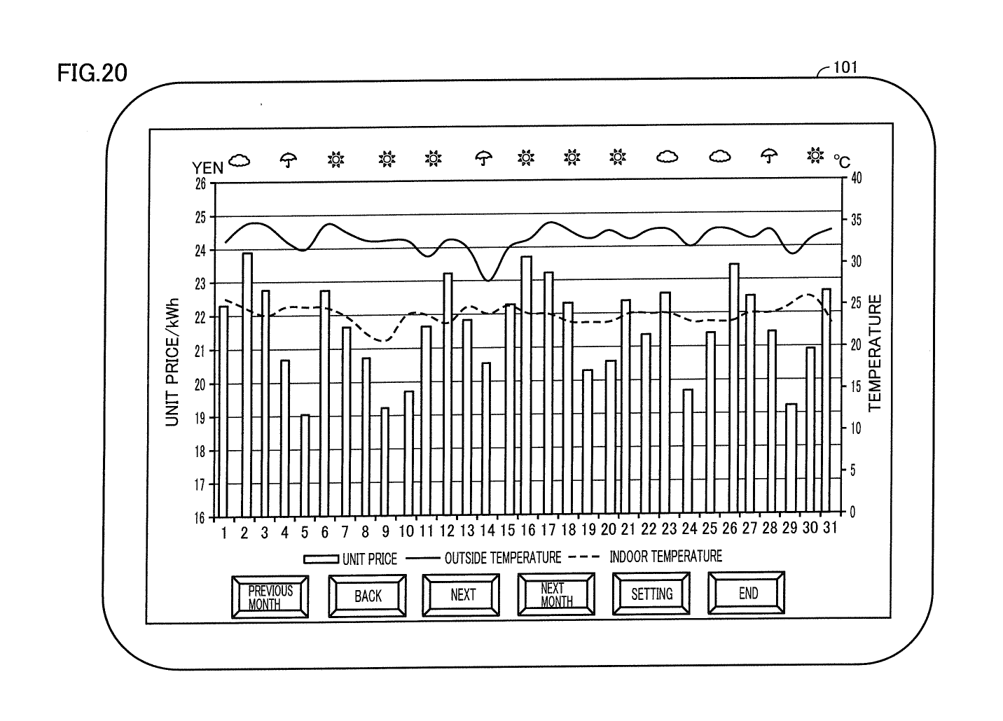

FIG. 20 represents another display screen of terminal device 101. FIG. 20 is a transitional image from FIG. 19. Referring to FIG. 20, terminal device 101 displays the unit price of the electricity rate, outside temperature, indoor temperature, and weather temperature on a daily basis in the form of a graph, based on information received from server device 202B. The user of terminal device 101 can look at the graph shown in FIG. 20 to identify how the unit price is changing based on the weather, outside temperature and indoor temperature.

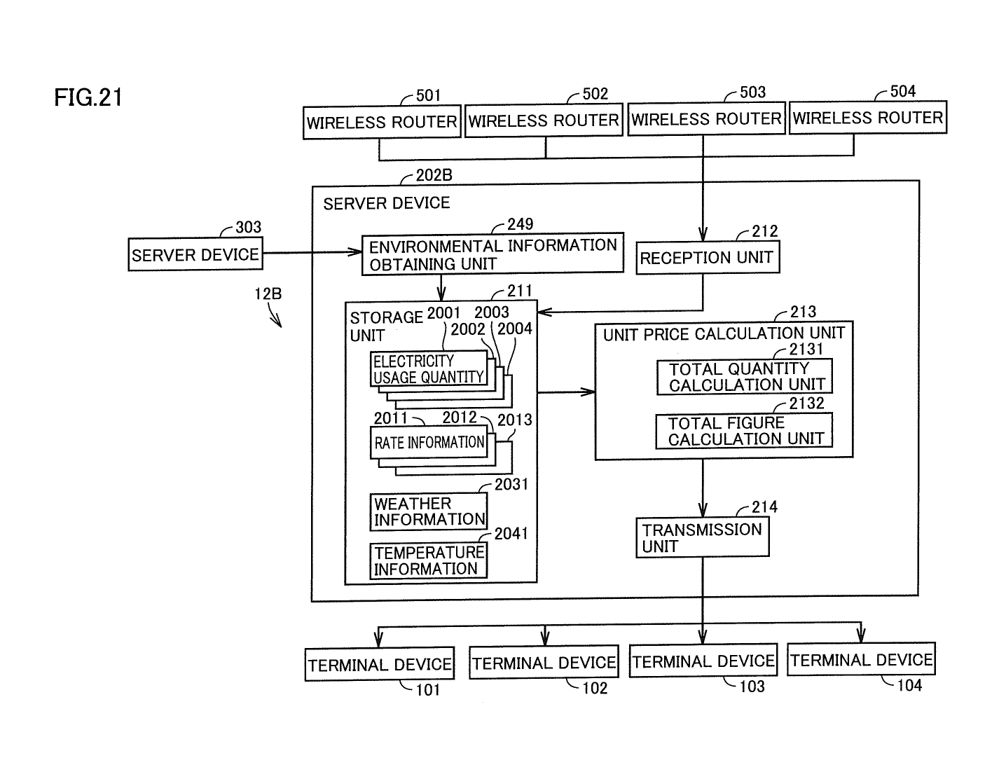

FIG. 21 is a diagram to describe a functional configuration of server device 202B. Referring to FIG. 21, server device 202B includes a storage unit 211, a reception unit 212, a unit price calculation unit 213, a transmission unit 214, and an environmental information obtaining unit 249.

Environmental information obtaining unit 249 obtains and stores into storage unit 211 weather information and outside temperature information from server device 303. Reception unit 212 receives indoor temperature from each wireless router. Server device 202B may obtain information on outside temperature from server device 303.

Storage unit 211 includes a file 2031 of weather information and a file 2041 of temperature information (outside temperature and indoor temperature), as compared to the configuration of server device 201 of the first embodiment. Weather information file 2031 includes the weather information related to each premises on a daily basis. Temperature information file 2041 includes the temperature information related to each premises (for example, average temperature) at least on a daily basis.

Transmission unit 214 transmits weather information and temperature information for the premises corresponding to the terminal device from which information transmission has been requested together with the various information of the interest of transmission set forth above (total quantity of electricity usage quantity, total figure of the electricity rate, unit price and the like) to the relevant terminal device.

Each process set forth above at communication system 12B can be realized utilizing communication system 13 described in the third embodiment.

### Eighth Embodiment

In the present embodiment, another configuration utilizing communication system 12 (FIG. 7) described in the second embodiment will be set forth below. For the sake of convenience, the communication system in the present embodiment is referred to as “communication system 12C” and the server device in communication system 12C is referred to as a server device 202C, as represented in parentheses in FIG. 7.

Server device 202C stores the contract applied to each premises among a plurality of contract plans related to the electricity rate. When transmitting information such as the total quantity of electricity usage quantity of each premises, server device 202C transmits in correspondence information to identify the contract plan entered by each premises (specifically, the electric power company and contract plan). Each terminal device 101 receives from server device 202C information related to its own device.

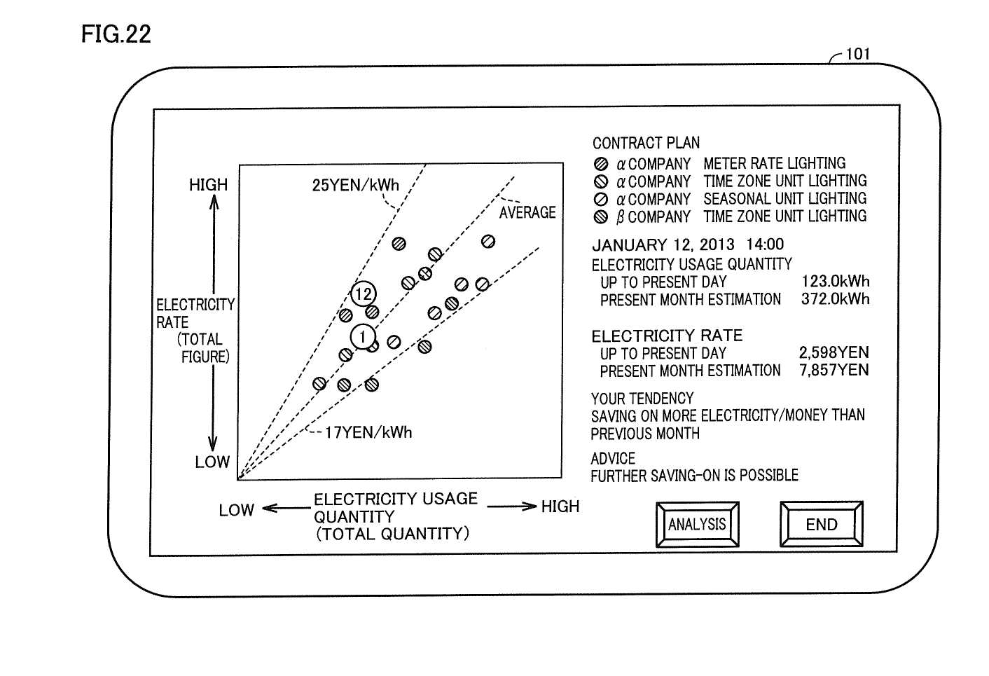

FIG. 22 represents a display screen by terminal device 101. Referring to FIG. 22, terminal device 101 displays on the monitor an image based on the information received from server device 202C. Specifically, terminal device 101 displays the graph shown in FIG. 2 together with the information of the contract plan. More specifically, terminal device 101 displays a circle representing information in the graph of each premises in a manner differing for every contract plan, together with indication therebetween.

Therefore, the user of terminal device 101 can look at the image shown in FIG. 22 to identify which contract plan of which company is located in the region where the unit price is low.

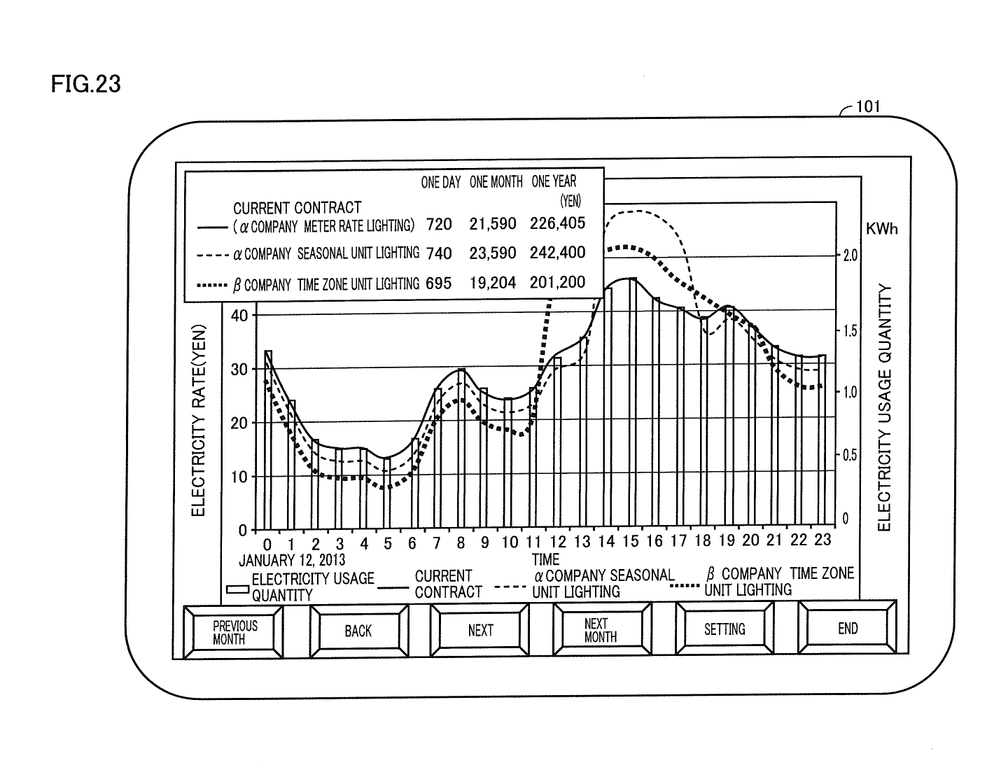

FIG. 23 represents another display screen by terminal device 101, which is a transitional image from the display screen of FIG. 22. Specifically, FIG. 23 shows the electricity rate and electricity usage quantity on an hourly basis at a specified day. Referring to FIG. 23, terminal device 101 displays, not only the contract plan currently entered (meter rate lighting of company α), but also other contract plans (for example, seasonal unit lighting of company α, time zone unit lighting of company β). At this stage, terminal device 101 also displays the actual value of the electricity rate of one day, and an estimation value of the electricity rate of one month and one year of each plan based on the information sent from server device 202C.

The user of terminal device 101 can look at the image shown in FIG. 23 to identify “how much money can be saved by changing the contract plan to another contract plan”.

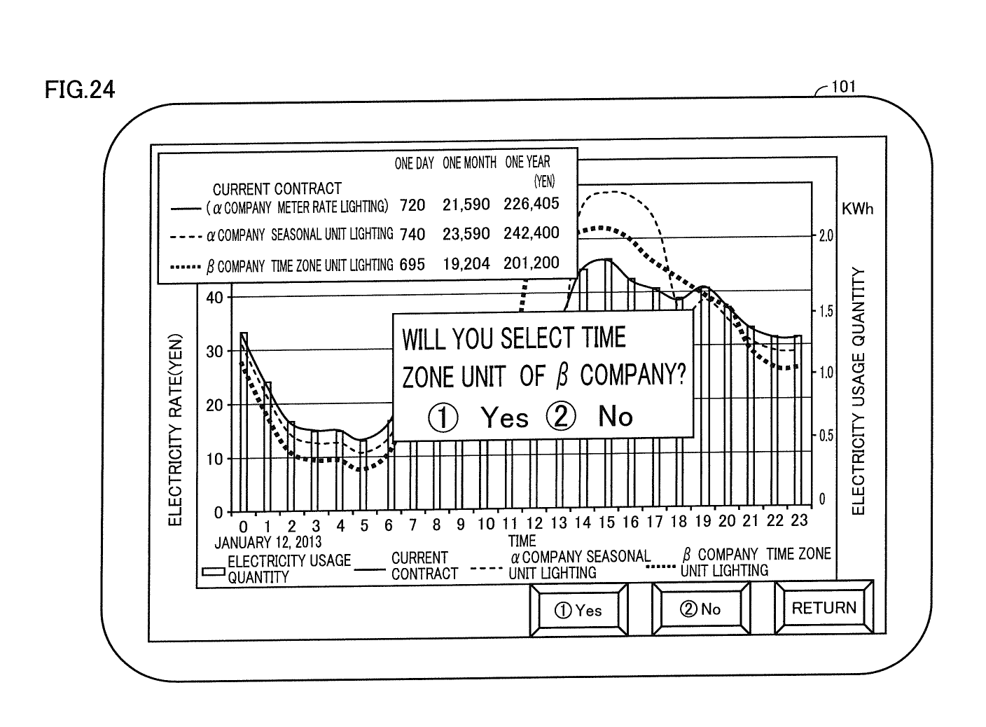

FIG. 24 represents a display screen that may be presented when another contract plan is to be selected. FIG. 24 is a transitional image from the display screen of FIG. 23. Referring to FIG. 24, terminal device 101 displays an image for confirmation (confirmation screen) in response to accepting an input by the user of terminal device 101 designating the selection of the time zone unit lighting of company β.

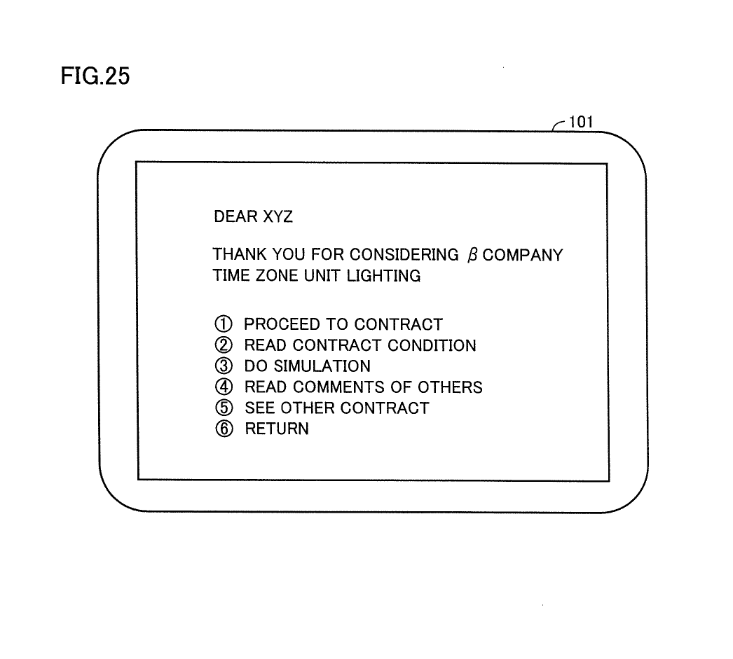

FIG. 25 represents a transitional image following the selection of (1) YES in FIG. 24. Referring to FIG. 25, terminal device 101 communicates with server device 202C to display an image for selection (selection screen) to execute modification of the contract plan.

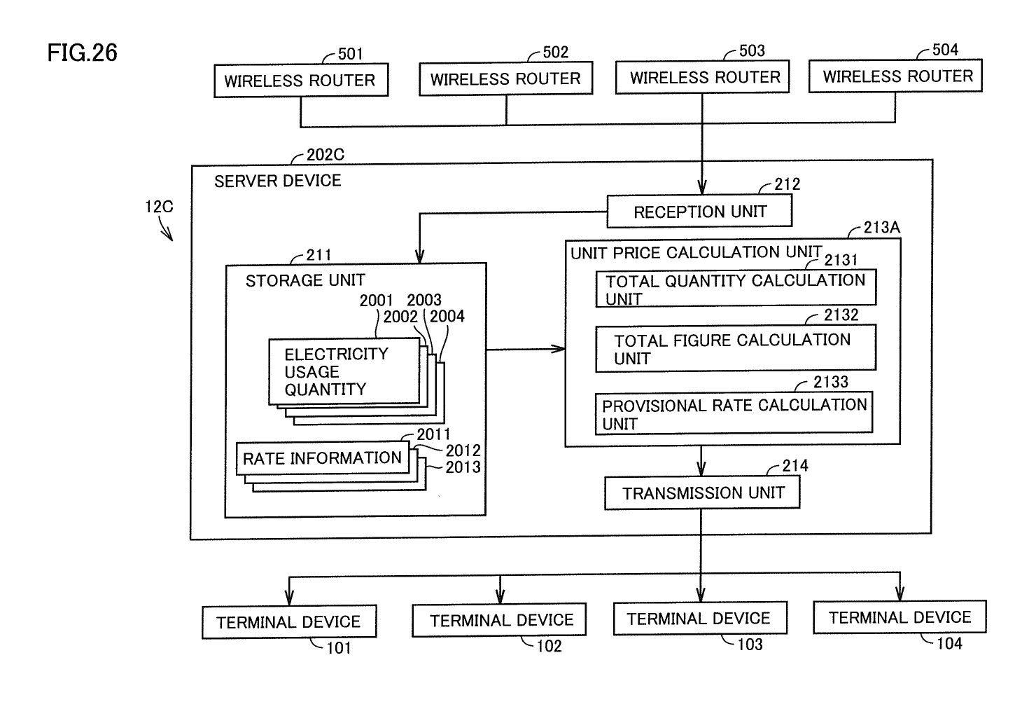

FIG. 26 is a diagram to describe a functional configuration of server device 202C. Referring to FIG. 26, server device 202C includes a storage unit 211, a reception unit 212, a unit price calculation unit 213A, and a transmission unit 214. Unit price calculation unit 213A includes a total quantity calculation unit 2131, a total figure calculation unit 2132, and a provisional rate calculation unit 2133.

Storage unit 211 stores the contract applied to each premises among the plurality of contract plans associated with the electricity rate, as compared to the configuration of server device 201 of the first embodiment.

Transmission unit 214 transmits to the terminal device from which information transmission has been requested information to identify the contract plan entered by each premises (electric power company and contract plan) in the transmission of various information of the interest of transmission set forth above (total quantity of electricity usage quantity, total figure of the electricity rate, unit price and the like) in correspondence.

Provisional rate calculation unit 2133 calculates for each premises the total figure of the electricity rate at a relevant premises assuming that a contract differing from the contract applied to the premises has been entered, among the plurality of contract plans. In this case, transmission unit 214 also transmits to the terminal device from which information transmission has been requested the total figure of the electricity rate of a specified term (for example, one day, one month, one year) assuming that a different contract has been entered.

Each process set forth above at communication system 12C can be realized utilizing communication system 18 described in the third embodiment.

<Example of Modification>

(1) In the graphs of FIG. 2 and the like, the total quantity of electricity usage quantity is plotted along the horizontal axis and the total figure of the electricity rate is plotted along the vertical axis. The representation is not limited thereto, and the vertical axis and the horizontal axis may be exchanged.

(2) For the sake of convenience, the above description has been described based on, but not limited to a premises. The unit of installment of a wireless router communicating with the server device is at least one for each residence. In other words, the wireless router may be installed on a mansion housing unit of a multi-dwelling building basis such as an apartment, or a room basis such as in an office building.

(3) The above description is based on, but not limited to a configuration in which the image shown in FIG. 2 is generated and displayed by terminal device 101 using an application program stored in its own device. A configuration in which the server device generates image data to display the image shown in FIG. 2, and transmits the relevant image data to a terminal device may be employed. In this case, the terminal device does not have to perform the process of generating image data.

<Overview>

(1) A server device (201, 201A, 202, 202A, 202B, 202C, 203) communicates with a first communication device (501) located at first residence (901), a second communication device (502) located at a second residence (902), and an electronic apparatus (101) used by the user of the first communication device. The server device includes a reception unit (212) receiving an electricity usage quantity by the first residence from the first communication device, and an electricity usage quantity by the second residence from the second communication device; a storage unit (211) storing each electricity usage quantity in correspondence with a date and time when the electricity is used, and rate information representing electricity rate on a time zone basis, a total quantity calculation unit (2131) calculating the total quantity of electricity usage quantity by the first residence and the total quantity of electricity usage quantity by the second residence over a predetermined first term based on each electricity usage quantity; a total figure calculation unit (2132) calculating the total figure of the electricity rate by the first residence and the total figure of the electricity rate by the second residence over the first term based on each electricity usage quantity stored in correspondence with the time and date, and the rate information; and a transmission unit (214) transmitting to the electronic apparatus the total quantity of electricity usage quantity and the total figure of the electricity rate by the first residence in association, and the total quantity of electricity usage quantity and the total figure of the electricity rate by the second residence in association.

According to the configuration set forth above, the electronic apparatus can receive from the server device information having the total quantity of electricity usage quantity by the first residence associated with the total figure of the electricity rate by the first residence, and information having the total quantity of electricity usage quantity by the second residence associated with the total figure of the electricity rate by the second residence. Therefore, the user of the electronic apparatus can be informed of the total quantity of electricity usage quantity and the total figure of the electricity rate by the first residence and the total quantity of electricity usage quantity and the total figure of the electricity rate by the second residence. Thus, the user of the electronic apparatus can readily determine whether electricity is being used economically by the electricity user including the electricity contractor, as compared to another residence.

(2) Preferably, the total quantity calculation unit (2131) further calculates the total quantity of electricity usage quantity by the first residence over a second term previous to and identical in length with the first term. The total figure calculation unit (2132) further calculates the total figure of electricity rate of the first residence over the second term. The transmission unit (214) also transmits to the electronic apparatus the total quantity of electricity usage quantity and the total figure of the electricity rate by the first residence in association over the second term.

According to the configuration set forth above, the electronic apparatus can receive information of the total quantity of electricity usage quantity and the total figure of the electricity rate of the first residence in association over the second term. Therefore, the user of the electronic apparatus can compare the information of the first term with the information of the second term.

(3) Preferably, the server device (201, 201A, 202, 202A, 202B, 202C, 203) further includes a unit price calculation unit (213, 213A) calculating the unit price per unit electricity for each of the first and second residences over the first term. The transmission unit (214) also transmits to the electronic apparatus first unit price information representing the unit price for the first residence and second unit price information representing the unit price for the second residence.

According to the configuration set forth above, the electronic apparatus can further receive first unit price information representing the unit price for the first residence and second unit price information representing the unit price for the second residence. Therefore, the user of the electronic apparatus can compare the unit price of the second residence (the residence of another person) with the electronic apparatus of the first residence (his/her own residence).

(4) Preferably, server device (201, 201A, 202, 202A, 202B, 202C, 203) further communicates with a plurality of third communication devices (503, 504) differing from the first communication device and second communication device. Each of the third communication devices is provided at a residence differing from and excluding the first residence and second residence. The unit price calculation unit (213, 213A) calculates the unit price of electricity rate per unit electricity at each residence where a third communication device is located. The transmission unit (214) transmits to the electronic apparatus ranking information representing the ranking of unit price of the first residence among the unit price of the first residence, the unit price of the second residence, and the unit price of each residence where a third communication device is located.

According to the configuration set forth above, the electronic apparatus can further receive ranking information representing the ranking of the unit price of the first residence from the unit price of the first residence, the unit price of the second residence, and the unit price of each residence where a third communication device is located. Accordingly, the user of the electronic apparatus can identify his/her own ranking. Therefore, the server device can offer the user of the electronic apparatus an incentive to address saving-on through the electronic apparatus.

(5) Preferably, the reception unit (212) further receives the electricity usage quantity of each of a plurality of household appliances located at the first residence. The first term is one month of the present month. The total quantity calculation unit (2131) also calculates an estimation value of the total quantity of electricity usage quantity by the first residence when the first term has elapsed from the total quantity of electricity usage quantity by the first residence at the current point in time. The server device (202) further includes a ratio calculation unit (230) calculating the ratio of the electricity usage quantity by each household appliance to the estimation value, and the ratio of the electricity usage by each household appliance to the electricity usage quantity by one residence over the second term. The transmission unit (214) also transmits to the electronic apparatus the ratio information representing each calculated ratio.

According to the configuration set forth above, the user of the electronic apparatus can confirm the estimation value of the electricity rate of the present month (first term) and the total figure of the electricity rate of the second term in comparison. Further, the relevant user can identify the household appliance among the plurality of household appliances with a higher usage frequency as compared to the previous month. Therefore, the server device can offer the user an incentive to suppress usage of the household appliance with a higher frequency for the relevant user through the electronic apparatus.

(6) Preferably, the total figure calculation unit (2132) further calculates an estimation value of the total figure of the electricity rate by the first residence when the first term has elapsed in a case where at least one of the plurality of household appliances is replaced by purchase with a preliminarily household appliance of a manufacturer identical to or different from the manufacturer of the household appliance. The transmission unit (214) transmits to the electronic apparatus the total figure of the electricity rate when a household appliance is replaced by purchase.

According to the configuration set forth above, purchase replacement of a household appliance can be promoted to the user of the electronic apparatus.

(7) Preferably, the storage unit (211) further stores a first threshold value associated with a unit price. The server device (202A) further includes a determination unit (240) determining whether the unit price of the first residence and the unit price of the second residence is greater than or equal to the first threshold value. The transmission unit (214) transmits to the electronic apparatus a message prompting saving-on money when the unit price of the first residence is greater than or equal to the first threshold value. According to the configuration set forth above, the server device can prompt the user of the electronic apparatus of saving-on money.

(8) Preferably, the storage unit (211) further stores a second threshold value related to electricity usage quantity. The determination unit (240) further determines whether the electricity usage quantity by the first residence and by the second residence is greater than or equal to the second threshold value. The transmission unit (214) transmits a message prompting saving-on electricity to the electronic apparatus when the electricity usage quantity at the first residence is greater than or equal to the second threshold value. According to the configuration set forth above, the server device can prompt the user of the electronic apparatus of saving-on electricity.

(9) Preferably, the server device (202B) obtains external environmental information including at least one of the weather and temperature on a time zone basis from an external device. The storage unit (211) stores each obtained electricity usage quantity in association with the obtained external environmental information. The transmission unit (214) further transmits to the electronic apparatus the first unit price information and the second unit price information over the first term, and the external environmental information over the first term. According to the configuration set forth above, the user of the electronic apparatus can determine the relationship between the unit price and weather.

(10) Preferably, the storage unit (211) stores, as rate information, the rate information according to each of a plurality of contracts related to the electricity rate, and a contract applied to each of the first residence and the second residence from the plurality of contracts. The transmission unit (214) transmits to the electronic apparatus information to identify the contract applied to the first residence in association with the total quantity of electricity usage quantity and the total figure of the electricity rate at the first residence, and information to identify the contract applied to the second residence in association with the total quantity of electricity usage quantity and the total figure of the electricity rate at the second residence. According to the configuration set forth above, the user of the electronic apparatus can identify which contract can lead to a lower unit price.

(11) Preferably, the storage unit (211) stores, as rate information, the rate information according to each of a plurality of contracts related to the electricity rate, and the contract applied to the first residence among the plurality of contracts. The server device (202C) further includes a provisional rate calculation unit (2133) calculating the total figure of electricity rate of a specified term at the first residence assuming that a contract from the plurality of contracts, differing from the contract applied to the first residence, is entered. The transmission unit (214) transmits to the electronic apparatus (101) the total figure of the electricity rate assuming that the different contract has been entered. According to the configuration set forth above, the user of the electronic apparatus can be informed of the total figure of the electricity rate when changing to another contract. Therefore, the server device can prompt the user of the electronic apparatus to change the contract.

(12) The server device (201, 201A, 202, 202A, 202B, 202C, 203) communicates with a first communication device (501) located at a first residence, a second communication device (502) located at a second residence, and an electronic apparatus (101) used by a user of the first communication device. The server device includes a reception unit receiving an electricity usage quantity by the first residence from the first communication device and an electricity usage quantity by the second residence from the second communication device, a storage unit (211) storing each electricity usage quantity in correspondence with a time and date when the electricity is used, and rate information representing an electricity rate on a time zone basis, a unit price calculation unit (213) calculating a unit price of the electricity rate per unit electricity at each of the first residence and second residence over a predetermined first term based on each electricity usage quantity and rate information, and a transmission unit (214) transmitting to the electronic apparatus first unit price representing the unit price of the first residence and second unit price representing the unit price of the second residence.

According to the configuration set forth above, the electronic apparatus can receive from the server device first unit price information representing the unit price of the first residence and second unit price information representing the unit price of the second residence. Accordingly, the user of the electronic apparatus can be informed of the unit price of the first residence and the unit price of the second residence. Thus, the user of the electronic apparatus can readily determine whether the electricity user including the electricity contractor is using electricity economically as compared to other residences.

(13) The server devices (201, 201A, 202, 202A, 202B, 202C, 203) communicates with a first communication device (501) located at a first residence, a second communication device (502) located at a second residence, and an electronic apparatus (101) used by a user of the first communication device. The server device includes a reception unit (212) receiving an electricity usage quantity by the first residence from the first communication device and an electricity usage quantity by the second residence from the second communication device, a storage unit (211) storing each electricity usage quantity in correspondence with a time and date when the electricity is used, and rate information representing the electricity rate on a time zone basis, a total quantity calculation unit (2131) calculating the total quantity of electricity usage quantity by the first residence and the total quantity of electricity usage quantity by the second residence over a predetermined first term based on each electricity usage quantity, a total figure calculation unit (2132) calculating the total figure of the electricity rate by the first residence and the total figure of the electricity rate by the second residence over the first term based on each electricity usage quantity stored in correspondence with the time and date, and the rate information, a generation unit generating image data having the total quantity of electricity usage quantity by the first residence associated with the total figure of the electricity rate by the first residence and the total quantity of electricity usage quantity by the second residence associated with the total figure of the electricity rate by the second residence, and a transmission unit (214) transmitting the generated image data to the electronic apparatus.

According to the configuration set forth above, the electronic apparatus can receive from the server device image data having the total quantity of electricity usage quantity by the first residence associated with the total figure of the electricity rate by the first residence and the total quantity of electricity usage quantity by the second residence associated with the total figure of the electricity rate by the second residence. Therefore, the user of the electronic apparatus can be informed of the total quantity of electricity usage quantity and the total figure of the electricity rate by the first residence and the total quantity of electricity usage quantity and the total figure of the electricity rate by the second residence. Thus, the user of the electronic apparatus can readily determine whether electricity is being used economically by the electricity user including the electricity contractor, as compared to another residence.

(14) An electronic apparatus (101) communicates with a server device communicating with a communication device located at one residence. The electronic apparatus includes a reception unit (1011) receiving from the server device information representing the total quantity of electricity usage quantity and the total figure of the electricity rate at the one residence over a predetermined time, and the total quantity of electricity usage quantity and the total figure of the electricity rate at a residence differing from the one residence over the predetermined term, based on the server device obtaining the electricity usage quantity at the one residence from the communication device, and an output unit (1012) providing an output based on the received total quantity of electricity usage quantity and the total figure of the electricity rate.

According to the configuration set forth above, the electronic apparatus can receive from the server device information having the total quantity of electricity usage quantity associated with the total figure of the electricity rate at one residence, and information having the total quantity of electricity usage quantity associated with the total figure of the electricity rate of another residence. Therefore, the user of the electronic apparatus can be informed of the total quantity of electricity usage quantity and the total figure of the electricity rate of one residence and the total quantity of electricity usage quantity and the total figure of the electricity rate of another residence. Thus, the user of the electronic apparatus can readily determine whether electricity is being used economically by the electricity user including the electricity contractor, as compared to another residence.

(15) Preferably, the output unit (1012) provides a display representing the unit price per unit electricity for each of the one residence and another residence. Therefore, the user of the electronic apparatus can be informed of the unit price per unit electricity for each of the one residence and another residence. Thus, the user of the electronic apparatus can readily compare the unit price of the one residence and the unit price of another residence.

(16) Preferably, the output unit (1012) displays the total quantity of electricity usage quantity and the total figure of the electricity rate at one residence and the total quantity of electricity usage quantity and the total figure of the electricity rate of another residence in a two-dimensional graph. One of the vertical axis and horizontal axis of the graph represents the total quantity of electricity usage quantity whereas the other represents the total figure of the electricity rate. According to the configuration set forth above, the user of the electronic apparatus can visually confirm the total quantity of electricity usage quantity and the total figure of the electricity rate for one residence and the total quantity of electricity usage quantity and the total figure of the electricity rate for another residence. Since the unit price is the total figure of the electricity rate divided by the total quantity of electricity usage quantity, the user of the electronic apparatus can be informed of the approximate figure of the unit price.

(17) According to still another aspect of the present invention, a communication system (11, 11A, 12, 12A, 12B, 12C, 13) includes a first communication device (501) located at a first residence (901), a second communication device (502) located at the second residence (902), an electronic apparatus (101) used by a user of the first communication device, and a server device (201, 201A, 202, 202A, 202B, 202C, 203). The server device includes a reception unit (212) receiving an electricity usage quantity by the first residence from the first communication device and the electricity usage quantity by the second residence from the second communication device; a storage unit (211) storing each electricity usage quantity in correspondence with a time and date when electricity is used, and rate information representing an electricity rate on a time zone basis; a total quantity calculation unit (2131) calculating the total quantity of electricity usage quantity by the first residence and the total quantity of electricity usage quantity by the second residence over a predetermined term based on each electricity usage quantity; a total figure calculation unit (2132) calculating the total figure of the electricity rate by the first residence and the total figure of the electricity rate by the second residence over the predetermined term based on each electricity usage quantity stored in correspondence with a time and date, and the rate information; and a transmission unit (214) transmitting to the electronic apparatus the total quantity of electricity usage quantity and the total figure of the electricity rate by the first residence in association, and the total quantity of electricity usage quantity and the total figure of the electricity rate by the second residence in association. The electronic apparatus includes a reception unit (1011) receiving information representing the total quantity of electricity usage quantity and the total figure of the electricity rate by the first residence and the total quantity of electricity usage quantity and the total figure of the electricity rate by the second residence over a predetermined term from the server device; and an output unit (1012) providing an output based on the received total quantity of electricity usage quantity and the total figure of the electricity rate.

According to the configuration set forth above, the electronic apparatus can receive from the server device information having the total quantity of electricity usage quantity by the first residence associated with the total figure of the electricity rate by the first residence, and information having the total quantity of electricity usage quantity by the second residence associated with the total figure of the electricity rate by the second residence. Therefore, the user of the electronic apparatus can be informed of the total quantity of electricity usage quantity and the total figure of the electricity rate by the first residence and the total quantity of electricity usage quantity and the total figure of the electricity rate by the second residence. Thus, the user of the electronic apparatus can readily determine whether electricity is being used economically by the electricity user including the electricity contractor, as compared to another residence.

(18) An information processing method is executed at a server device (201, 201A, 202, 202A, 202B, 202C, 203) communicating with a first communication device (501) located at a first residence (901), a second communication device (502) located at a second residence (902), and an electronic apparatus (101) used by a user of the first communication device. The information processing method includes the steps of receiving an electricity usage quantity by a first residence from the first communication device and receiving an electricity usage quantity by a second residence from the second communication device, by the server device; storing each electricity usage quantity in correspondence with a time and date of electricity usage, and rate information representing an electricity rate on a time zone basis, by the server device; calculating a total quantity of electricity usage quantity by the first residence and the total quantity of electricity usage quantity by the second residence over a predetermined first term based on each electricity usage quantity, by the server; calculating a total figure of the electricity rate by the first residence and a total figure of the electricity rate by the second residence over the first term based on each electricity usage quantity stored in correspondence with the time and date and the rate information, by the server; and transmitting to the electronic apparatus the total quantity of electricity usage quantity and the total figure of the electricity rate by the first residence in association, and the total quantity of electricity usage quantity and the total figure of the electricity rate by the second residence in association, by the server device.

According to the configuration set forth above, the electronic apparatus can receive from the server device information having the total quantity of electricity usage quantity by the first residence associated with the total figure of the electricity rate by the first residence, and information having the total quantity of electricity usage quantity by the second residence associated with the total figure of the electricity rate by the second residence. Therefore, the user of the electronic apparatus can be informed of the total quantity of electricity usage quantity and the total figure of the electricity rate by the first residence and the total quantity of electricity usage quantity and the total figure of the electricity rate by the second residence. Thus, the user of the electronic apparatus can readily determine whether electricity is being used economically by the electricity user including the electricity contractor, as compared to another residence.

(19) An information processing method is executed at an electronic apparatus (101) communicating with a server device (201, 201A, 202, 202A, 202B, 202C, 203) communicating with a communication device (501) located at a residence. The information processing method includes the steps of: based on obtaining the electricity usage quantity by one residence from the communication device by the server device, receiving information representing the total quantity of electricity usage quantity and the total figure of the electricity rate by the one residence and representing the total quantity of electricity usage quantity and the total figure of the electricity rate by another residence differing from the one residence over a predetermined term, by the electronic apparatus; and providing an output based on the received total quantity of electricity usage quantity and total figure of the electricity rate by the electronic apparatus.

According to the configuration set forth above, the electronic apparatus can receive from the server device information having the total quantity of electricity usage quantity by the first residence associated with the total figure of the electricity rate by the first residence, and information having the total quantity of electricity usage quantity by the second residence associated with the total figure of the electricity rate by the second residence. Therefore, the user of the electronic apparatus can be informed of the total quantity of electricity usage quantity and the total figure of the electricity rate by the first residence and the total quantity of electricity usage quantity and the total figure of the electricity rate by the second residence. Thus, the user of the electronic apparatus can readily determine whether electricity is being used economically by the electricity user including the electricity contractor, as compared to another residence.

According to the configuration set forth above, the electronic apparatus can receive from the server device information having the total quantity of electricity usage quantity by one residence associated with the total figure of the electricity rate by the one residence, and information having the total quantity of electricity usage quantity by another residence associated with the total figure of the electricity rate by the other residence. Therefore, the user of the electronic apparatus can be informed of the total quantity of electricity usage quantity and the total figure of the electricity rate by the one residence and the total quantity of electricity usage quantity and the total figure of the electricity rate by the other residence. Thus, the user of the electronic apparatus can readily determine whether electricity is being used economically by the electricity user including the electricity contractor, as compared to another residence.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A server device communicating with a first communication device located at a first residence, a second communication device located at a second residence, and an electronic apparatus used by a user of said first communication device, said server device comprising:
a reception unit configured to receive an electricity usage quantity by said first residence from said first communication device and an electricity usage quantity by said second residence from said second communication device;
a storage unit storing each said electricity usage quantity in correspondence with a time and date when electricity is used, and storing rate information representing an electricity rate on a time zone basis;
a total quantity calculation unit configured to calculate a total quantity of electricity usage quantity by said first residence and a total quantity of electricity usage quantity by said second residence over a predetermined first term based on each said electricity usage quantity;
a total figure calculation unit configured to calculate a total figure of the electricity rate by said first residence and a total figure of the electricity rate by the second residence over said first term based on each said electricity usage quantity stored in correspondence with said time and date, and said rate information; and
a transmission unit configured to transmit to said electronic apparatus the total quantity of electricity usage quantity and the total figure of the electricity rate by said first residence in association, and the total quantity of electricity usage quantity and the total figure of the electricity rate by said second residence in association

2. The server device according to claim 1, wherein
said total quantity calculation unit further calculates the total quantity of electricity usage quantity by said first residence over a second term previous to said first term and identical in length with said first term,
said total figure calculation unit further calculating the total figure of the electricity rate at said first residence over said second term, and
said transmission unit further transmits to said electronic apparatus the total quantity of electricity usage quantity and the total figure of the electricity rate in association by said first residence over said second term.

3. The server device according to claim 1, further comprising a unit price calculation unit configured to calculate a unit price per unit electricity for each of said first residence and said second residence over said first term,
wherein said transmission unit transmits to said electronic apparatus first unit price information representing said unit price for said first residence and second unit price information representing said unit price for said second residence.

4. The server device according to claim 3, wherein
said server device further communicates with a plurality of third communication devices differing from said first communication device and said second communication device,
each of said third communication devices is located at a residence differing from and excluding said first residence and said second residence,
said unit price calculation unit calculates the unit price of the electricity rate per unit electricity for each residence where a third communication device is located,
said transmission unit further transmits to said electronic apparatus ranking information representing ranking of said unit price at said first residence from said unit price of said first residence, said unit price of said second residence, and said unit price of each residence where each said third communication device is located.

5. The server device according to claim 2, wherein
said reception unit further receives the electricity usage quantity by each of a plurality of household appliances provided at said first residence,
said first term is one month of a present month,
said total quantity calculation unit further calculates an estimation value of a total quantity of electricity usage quantity by said first residence when said first term has elapsed from the total quantity of electricity usage quantity by said first residence at a current point in time,
said server device further including a ratio calculation unit configured to calculate a ratio of an electricity usage quantity by each household appliance to said estimation value, and a ratio of the electricity usage quantity by each household appliance to said electricity usage quantity by said first residence over said second term, and
said transmission unit further transmits to said electronic apparatus ratio information representing each said calculated ratio.

6. The server device according to claim 5, wherein
said total figure calculation unit further calculates an estimation value of the total figure of the electricity rate by said first residence when said first term has elapsed in a case where at least one of said plurality of household appliances is replaced by purchase with a preliminarily specified household appliance of a manufacturer identical to or different from said preliminarily specified household appliance,
said transmission unit further transmits to said electronic apparatus the total figure of the electricity rate when said household appliance is replaced by purchase.

7. The server device according to claim 3, wherein said storage unit further stores a first threshold value related to said unit price,
said server device further including a determination unit determining whether said unit price of the first residence and said unit price of the second residence is greater than or equal to the first threshold value,
wherein said transmission unit transmits to said electronic apparatus a message prompting saving-on money when said unit price of the first residence is greater than or equal to said first threshold value.

8. The server device according to claim 7, wherein
said storage unit further stores a second threshold value related to said electricity usage quantity,
said determination unit further determines whether said electricity usage quantity by the first residence and by the second residence is greater than or equal to said second threshold value, and
said transmission unit transmits a message prompting saving-on electricity to said electronic apparatus when said electricity usage quantity by said first residence is greater than or equal to the second threshold value.

9. The server device according to claim 3, wherein
said server device obtains external environmental information including at least one of weather and temperature on a time zone basis from an external device,
said storage unit stores each obtained electricity usage quantity in association with said obtained external environmental information, and
said transmission unit further transmits to said electronic apparatus said first unit price information and said second unit price information over said first term, and said external environmental information over said first term.

10. The server device according to claim 1, wherein
said storage unit stores, as said rate information, rate information according to each of a plurality of contracts related to said electricity rate, and a contract applied to each of said first residence and said second residence from said plurality of contracts, and
said transmission unit transmits to said electronic apparatus information to identify the contract applied to said first residence in association with the total quantity of electricity usage quantity and the total figure of the electricity rate at said first residence, and information to identify the contract applied to said second residence in association with the total quantity of electricity usage quantity and the total figure of the electricity rate at said second residence.

11. The server device according to claim 1, wherein said storage unit stores, as said rate information, rate information according to each of a plurality of contracts related to said electricity rate, and a contract applied to said first residence among said plurality of contracts,
said server device further including a provisional rate calculation unit configured to calculate the total figure of electricity rate of a specified term at the first residence assuming that a contract from the plurality of contracts, differing from the contract applied to the first residence, is entered,
wherein said transmission unit transmits to said electronic apparatus the total figure of the electricity rate assuming that the different contract has been entered.

12. A server device communicating with a first communication device located at a first residence, a second communication device located at a second residence, and an electronic apparatus used by a user of the first communication device, said server device comprising:
a reception unit receiving an electricity usage quantity by said first residence from said first communication device and an electricity usage quantity by said second residence from said second communication device;
a storage unit storing each said electricity usage quantity in correspondence with a time and date when electricity is used, and rate information representing an electricity rate on a time zone basis;
a unit price calculation unit configured to calculate a unit price of the electricity rate per unit electricity at each of said first residence and said second residence over a predetermined first term, based on each said electricity usage quantity and said rate information; and
a transmission unit configured to transmit to said electronic apparatus first unit price information representing said unit price at said first residence and second unit price information representing said unit price at said second residence.

13. A server device communicating with a first communication device located at a first residence, a second communication device located at a second residence, and an electronic apparatus used by a user of the first communication device, said server device comprising:
a reception unit receiving an electricity usage quantity by said first residence from said first communication device and an electricity usage quantity by said second residence from said second communication device;
a storage unit storing each said electricity usage quantity in correspondence with a time and date when electricity is used, and rate information representing an electricity rate on a time zone basis;
a total quantity calculation unit configured to calculate a total quantity of electricity usage quantity by said first residence and a total quantity of electricity usage quantity by said second residence over a predetermined first term based on each said electricity usage quantity;
a total figure calculation unit configured to calculate a total figure of the electricity rate by said first residence and a total figure of the electricity rate by the second residence over said first term based on each said electricity usage quantity stored in correspondence with said time and date, and said rate information;
a generation unit configured to generate image data having the total quantity of electricity usage quantity by said first residence associated with the total figure of the electricity rate by said first residence and the total quantity of electricity usage quantity by said second residence associated with the total figure of the electricity rate by said second residence; and
a transmission unit configured to transmit said generated image data to said electronic apparatus.

14. An electronic apparatus communicating with a server device communicating with a communication device located at one residence, said electronic apparatus comprising:
a reception unit configured to receive from said server device information representing a total quantity of electricity usage quantity and a total figure of an electricity rate at said one residence over a predetermined term, and a total quantity of electricity usage quantity and a total figure of an electricity rate at another residence differing from said one residence over a predetermined term, based on obtaining an electricity usage quantity by said one residence from said communication device; and
an output unit configured to provide an output based on said received total quantity of electricity usage quantity and total figure of the electricity rate.

15. The electronic apparatus according to claim 14, wherein said output unit provides a display representing a unit price per unit electricity for each of said one residence and other residence.

16. The electronic apparatus according to claim 15, wherein
said output unit displays the total quantity of electricity usage quantity and the total figure of the electricity rate at said one residence and the total quantity of electricity usage quantity and the total figure of the electricity rate at said other residence in a two-dimensional graph,
one of a vertical axis and a horizontal axis of said graph represents the total quantity of electricity usage quantity, and the other of a vertical axis and a horizontal axis represents the total figure of the electricity rate.

17. A communication system comprising a first communication device located at a first residence, a second communication device located at a second residence, an electronic apparatus used by a user of said first communication device, and a server device,
said server device including:
a reception unit configured to receive an electricity usage quantity by said first residence from said first communication device and an electricity usage quantity by said second residence from said second communication device;
a storage unit storing each said electricity usage quantity in correspondence with a time and date when electricity is used, and storing rate information representing an electricity rate on a time zone basis;
a total quantity calculation unit configured to calculate a total quantity of electricity usage quantity by said first residence and a total quantity of electricity usage quantity by said second residence over a predetermined term based on each said electricity usage quantity;
a total figure calculation unit configured to calculate a total figure of an electricity rate by said first residence and a total figure of an electricity rate by the second residence over said predetermined term based on each said electricity usage quantity stored in correspondence with said time and date, and said rate information; and
a transmission unit configured to transmit to said electronic apparatus the total quantity of electricity usage quantity and the total figure of the electricity rate by said first residence in association, and the total quantity of electricity usage quantity and the total figure of the electricity rate by said second residence in association;
said electronic apparatus including:
a reception unit configured to receive from said server device information representing the total quantity of electricity usage quantity and the total figure of the electricity rate at said first residence over said predetermined term, and the total quantity of electricity usage quantity and the total figure of the electricity rate at said second residence over said predetermined term; and
an output unit configured to provide an output based on said received total quantity of electricity usage quantity and total figure of the electricity rate.

18. An information processing method of a server device communicating with a first communication device located at a first residence, a second communication device located at second residence, and an electronic apparatus used by a user of said first communication device, said information processing method comprising:
receiving, by said server device, an electricity usage quantity by said first residence from said first communication device and an electricity usage quantity by said second residence from said second communication device;
storing, by said server device, each said electricity usage quantity in correspondence with a time and date when electricity is used, and storing rate information representing an electricity rate on a time zone basis;
calculating, by said server device, a total quantity of electricity usage quantity by said first residence and a total quantity of electricity usage quantity by said second residence over a predetermined first term based on each said electricity usage quantity;
calculating, by said server device, a total figure of an electricity rate at said first residence and a total figure of an electricity rate at said second residence over said first term based on said each electricity usage quantity stored in correspondence with said time and date, and said rate information; and
transmitting, by said server device, to said electronic apparatus the total quantity of electricity usage quantity by said first residence and the total figure of the electricity rate at said first residence in association, and the total quantity of electricity usage quantity by said first residence and the total figure of the electricity rate at said second residence in association.

19. An information processing method of an electronic apparatus communicating with a server device communicating with a communication device located at one residence, said information processing method comprising:
receiving, by said electronic apparatus, based on obtaining an electricity usage quantity by said one residence from said communication device, by said server device, a total quantity of electricity usage quantity and a total figure of an electricity rate at said one residence, and a total quantity of electricity usage quantity and a total figure of an electricity rate at another residence differing from said one residence over a predetermined term; and
providing, by said electronic apparatus, an output based on said received total quantity of electricity usage quantity and the total figure of the electricity rate.
